(19) United States
(12) Patent Application Publication
(10) Pub. No.: US 2025/0008795 A1
(43) Pub. Date: Jan. 2, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Fei FANG, Beijing (CN); Ke LIU, Beijing (CN); Zeliang LI, Beijing (CN); Banghan ZHANG, Beijing (CN); Dan GUO, Beijing (CN); Ling SHI, Beijing (CN); Yangzhong JING, Beijing (CN)

(21) Appl. No.: 18/709,823

(22) PCT Filed: May 11, 2023
(86) PCT No.: PCT/CN2023/093438

§ 371 Date: May 14, 2024

(30) Foreign Application Priority Data
May 31, 2022 (CN) 202210615748.7

(51) Int. Cl. H10K 59/131; H10K 59/121; H10K 59/35; H10K 59/65

(52) U.S. Cl. CPC H10K 59/131; H10K 59/121; H10K 59/351; H10K 59/353; H10K 59/65

(57) ABSTRACT

Disclosed is a display substrate, comprising a first display area. The first display area comprises a plurality of display island areas spaced apart from each other, and light-transmissive areas located between adjacent display island areas. Each display island area comprises a plurality of first pixel circuits and a plurality of first light-emitting elements which are provided on a base. At least one first pixel circuit is electrically connected to at least one first light-emitting element, and is configured to drive the at least one first light-emitting element to emit light. The first pixel circuits in the display island areas which are adjacent in a first direction are electrically connected by means of first signal wires, and the first pixel circuits in the display island areas which are adjacent in a second direction are electrically connected by means of second signal wires. The first direction intersects with the second direction.

### CROSS-REFERENCE TO RELATED APPLICATIONS

The present application is a U.S. National Phase Entry of International Application No. PCT/CN2023/093438 having an international filing date of May 11, 2023, which claims the priority to the Chinese Patent Application No. 202210615748.7, filed to the CNIPA on May 31, 2022, contents of the above-identified applications should be regarded as being incorporated herein by reference.

### TECHNICAL FIELD

The present disclosure relates to the field of display technologies, in particular to a display substrate and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc.

### SUMMARY

The following is a summary of subject matters described herein in detail. The summary is not intended to limit the protection scope of claims.

Embodiments of the present disclosure provide a display substrate and a display apparatus.

In one aspect, an embodiment provides a display substrate including: a first display region. The first display region includes multiple display island regions spaced apart from each other, and a light-transmitting region located between adjacent display island regions. A display island region includes multiple first pixel circuits and multiple first light emitting elements disposed on a base substrate, at least one first pixel circuit among the multiple first pixel circuits is electrically connected with at least one first light emitting element among the multiple first light emitting elements, and the at least one first pixel circuit is configured to drive the at least one first light emitting element to emit light. First pixel circuits in adjacent display island regions in a first direction are electrically connected through a first signal trace, and first pixel circuits in adjacent display island regions in a second direction are electrically connected through a second signal trace; the first direction intersects with the second direction; and materials of the first signal trace and the second signal trace include transparent conductive materials.

In some exemplary implementation modes, at least portions of the first signal trace and the second signal trace are located in the light-transmitting region.

In some exemplary implementation modes, the display island region includes: four first pixel circuits and four first light emitting elements; the four first pixel circuits are electrically connected with the four first light emitting elements in one-to-one correspondence; and the four first pixel circuits are sequentially arranged along the first direction.

In some exemplary implementation modes, the four first light emitting elements include: a first light emitting element emitting light of a first color, a first light emitting element emitting light of a second color, and two first light emitting elements emitting light of a third color.

In some exemplary implementation modes, the first light emitting element emitting light of the first color and the first light emitting element emitting light of the second color are arranged in a same row, the two first light emitting elements emitting light of the third color are arranged in a same row, and the first light emitting element emitting light of the first color, one first light emitting element emitting light of the third color, the first light emitting element emitting light of the second color, and the other first light emitting element emitting light of the third color are arranged in different columns.

In some exemplary implementation modes, orthographic projections of light emitting regions of the two first light emitting elements emitting light of the third color on the base substrate are not overlapped with an orthographic projection of an electrically connected first pixel circuit on the base substrate. An orthographic projection of a light emitting region of the first light emitting element emitting light of the first color on the base substrate is overlapped with an orthographic projection of an electrically connected first pixel circuit on the base substrate. An orthographic projection of a light emitting region of the first light emitting element emitting light of the second color on the base substrate is overlapped with an orthographic projection of an electrically connected first pixel circuit on the base substrate.

In some exemplary implementation modes, an orthographic projection of a first light emitting element emitting light of the third color on the base substrate is overlapped with an orthographic projection of the second signal trace on the base substrate.

In some exemplary implementation modes, the multiple display island regions are arranged in multiple rows and columns, one row of display island regions includes multiple display island regions arranged along the first direction, and one column of display island regions includes multiple display island regions arranged along the second direction; two adjacent display island regions in at least one column of display island regions are arranged every other at least one row, and two adjacent display island regions in at least one row of display island regions are arranged every other at least one column.

In some exemplary implementation modes, the display island region includes: a first first pixel circuit, a second first pixel circuit, a third first pixel circuit, and a fourth first pixel circuit arranged in sequence along the first direction; a third first pixel circuit in a display island region of a k-th row and an m-th column is electrically connected with a first first pixel circuit in a (k+1)-th row and an (m+1)-th column through the second signal trace, and a fourth first pixel circuit in the display island region of the k-th row and the m-th column is electrically connected with a second first pixel circuit in the (k+1)-th row and the (m+1)-th column through the second signal trace; wherein k and m are integers.

In some exemplary implementation modes, the four first pixel circuits include a first first pixel circuit, a second first pixel circuit, a third first pixel circuit, and a fourth first pixel circuit arranged in sequence along the first direction. A second signal trace electrically connected with the first first pixel circuit of the display island region is at least partially parallel to a second signal trace electrically connected with the second first pixel circuit, and a second signal trace electrically connected with the third first pixel circuit is at least partially parallel to a second signal trace electrically connected with the fourth first pixel circuit. The second signal trace electrically connected with the first first pixel circuit and the second signal trace electrically connected with the fourth first pixel circuit are substantially symmetrical about a centerline of the four first pixel circuits in the first direction, and the second signal trace electrically connected with the second first pixel circuit and the second signal trace electrically connected with the third first pixel circuit are substantially symmetrical about the centerline of the four first pixel circuits in the first direction.

In some exemplary implementation modes, the first signal trace and the second signal trace are located on a side of the first pixel circuit away from the base substrate and located on a side of the first light emitting element close to the base substrate.

In some exemplary implementation modes, the first signal trace and the second signal trace are of a same layer structure.

In some exemplary implementation modes, the first signal trace is a straight line segment extending along the first direction and the second signal trace is a polyline segment extending along the second direction.

In some exemplary implementation modes, the first signal trace includes a first initial connection line for transmitting a first initial signal, a first scan connection line for transmitting a scan signal, a second scan connection line for transmitting a first reset control signal, and a light emitting control line for transmitting a light emitting control signal.

In some exemplary implementation modes, the second signal trace includes: a data line, a power supply connection line for transmitting a first voltage signal.

In some exemplary implementation modes, the display substrate further includes: a second display region located on at least one side of the first display region; the second display region includes multiple second pixel circuits and multiple second light emitting elements disposed on the base substrate, at least one second pixel circuit among the multiple second pixel circuits is electrically connected with at least one second light emitting element among the multiple second light emitting elements, and the at least one second pixel circuit is configured to drive the at least one second light emitting element to emit light.

In another aspect, an embodiment of the present disclosure provides a display apparatus, which includes the aforementioned display substrate.

In some exemplary implementation modes, the display apparatus further includes a sensor located at one side of a non-display surface of the display substrate, and an orthographic projection of the sensor on the display substrate is overlapped with the first display region of the display substrate.

Other aspects may be comprehended after drawings and detailed description are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with the embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 is an equivalent circuit diagram of a pixel circuit according to at least one embodiment of the present disclosure.

FIG. 3A and FIG. 3B are partial schematic diagrams of a first display region according to at least one embodiment of the present disclosure.

FIG. 4 is a schematic partial top view of a region S1 in FIG. 3B.

FIG. 5 is a schematic partial cross-sectional view along a Q-Q′ direction in FIG. 4.

FIG. 6 is a partially enlarged schematic view of a display substrate after a semiconductor layer is formed in FIG. 4.

FIG. 7A is a partially enlarged schematic view of the display substrate after a first conductive layer is formed in FIG. 4.

FIG. 7B is a schematic diagram of the first conductive layer in FIG. 7A.

FIG. 8A is a partially enlarged schematic view of the display substrate after a second conductive layer is formed in FIG. 4.

FIG. 8B is a schematic diagram of the second conductive layer in FIG. 8.

FIG. 9 is a partially enlarged schematic view of the display substrate after a third insulation layer is formed in FIG. 4.

FIG. 10A is a partially enlarged schematic view of the display substrate after a third conductive layer is formed in FIG. 4.

FIG. 10B is a schematic diagram of the third conductive layer in FIG. 10A.

FIG. 11 is a partially enlarged schematic view of the display substrate after a fourth insulation layer is formed in FIG. 4.

FIG. 12A is a partially enlarged schematic view of the display substrate after a transparent conductive layer is formed in FIG. 4.

FIG. 12B is a schematic diagram of the transparent conductive layer in FIG. 12A.

FIG. 13 is a partially enlarged schematic view of the display substrate after a fifth insulation layer is formed in FIG. 4.

FIG. 14A is a partially enlarged schematic view of the display substrate after a fourth conductive layer is formed in FIG. 4.

FIG. 14B is a schematic diagram of the fourth conductive layer in FIG. 14A.

FIG. 15 is a partially enlarged schematic view of the display substrate after a sixth insulation layer is formed in FIG. 4.

FIG. 16A is a partially enlarged schematic view of the display substrate after an anode layer is formed in FIG. 4.

FIG. 16B is a schematic diagram of the anode layer in FIG. 14A.

FIG. 17 is a schematic diagram of a display apparatus according to at least one embodiment of the present disclosure.

### DETAILED DESCRIPTION

The embodiments of the present disclosure will be described in detail below in combination with the drawings. Implementation modes may be implemented in multiple different forms. Those of ordinary skills in the art may easily understand such a fact that modes and contents may be transformed into other forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating orientations or positional relationships are used to illustrate positional relationships between the constituent elements with reference to the drawings, not to indicate or imply that a referred apparatus or element must have a specific orientation and be structured and operated with the specific orientation but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations.

In the specification, an “electrical connection” includes a case that constituent elements are connected together through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a circle, oval, triangle, rectangle, trapezoid, pentagon, or hexagon, etc. is not strictly speaking, but may be an approximate circle, oval, triangle, rectangle, trapezoid, pentagon, or hexagon, etc. Some small deformations due to tolerances may exist, for example, guide angles, curved edges, and deformations may exist.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends along the B direction” in the present disclosure means “the main portion of A extends along the B direction”.

An embodiment of the present disclosure provides a display substrate including: a first display region. The first display region includes multiple display island regions spaced apart from each other, and a light-transmitting region located between adjacent display island regions. A display island region includes multiple first pixel circuits and multiple first light emitting elements disposed on a base substrate. At least one first pixel circuit among the multiple first pixel circuits is electrically connected with at least one first light emitting element among the multiple first light emitting elements, and the at least one first pixel circuit is configured to drive the at least one first light emitting element to emit light. First pixel circuits in adjacent display island regions in a first direction are electrically connected through a first signal trace, and first pixel circuits in adjacent display island regions in a second direction are electrically connected through a second signal trace. Materials of the first signal trace and the second signal trace include transparent conductive materials. The first direction intersects with the second direction. For example, the first direction and the second direction are perpendicular to each other.

According to the display substrate provided by the embodiment, a diffraction effect of the display substrate may be reduced by centrally arranging multiple first pixel circuits and multiple first light emitting elements in the display island region. Moreover, arrangement space of the first signal trace and the second signal trace may be increased, thereby increasing widths of the first signal trace and the second signal trace, reducing loads of the first signal trace and the second signal trace, and improving a display defect of the display substrate.

In some exemplary implementation modes, at least portions of the first signal trace and the second signal trace may be located in the light-transmitting region. In some examples, the first signal trace and the second signal trace may extend from one display island region to another display island region through the light-transmitting region, thereby achieving signal transmission between first pixel circuits of adjacent display island regions. Moreover, the first signal trace and the second signal trace are made of transparent conductive materials, which may ensure a light transmittance of the light-transmitting region.

In some exemplary implementation modes, the display island region may include four first pixel circuits and four first light emitting elements. The four first pixel circuits and the four first light emitting elements may be electrically connected in one-to-one correspondence. The four first pixel circuits may be arranged sequentially along the first direction. In some examples, the four first pixel circuits and the four first light emitting elements may form one pixel unit. However, the embodiment is not limited thereto. In other examples, the display island region may include two first pixel circuits and two first light emitting elements, the two first pixel circuits and the two first light emitting elements may be electrically connected in one-to-one correspondence, and the two first pixel circuits may be sequentially arranged along the first direction.

In some exemplary implementation modes, the four first light emitting elements of the display island region may include a first light emitting element emitting light of a first color, a first light emitting element emitting light of a second color, and two first light emitting elements emitting light of a third color. For example, the light of the first color may be red light, the light of the second color may be blue light, and the light of light of the third color may be green light. However, the embodiment is not limited thereto.

In some exemplary implementation modes, in the display island region, a first light emitting element emitting light of a first color and a first light emitting element emitting light of a second color may be arranged in a same row, and two first light emitting elements emitting light of a third color may be arranged in a same row. The first light emitting element emitting light of the first color, one first light emitting element emitting light of the third color, the first light emitting element emitting light of the second color, and the other first light emitting element emitting light of the third color may be arranged in different columns. In the example, multiple first light emitting elements arranged along the first direction may be referred to as a row of first light emitting elements, and multiple first light emitting elements arranged along the second direction may be referred to as a column of first light emitting elements.

In some exemplary implementation modes, orthographic projections of light emitting regions of the two first light emitting elements emitting light of the third color of the display island region on the base substrate and an orthographic projection of an electrically connected first pixel circuit on the base substrate may not be overlapped. An orthographic projection of a light emitting region of the first light emitting element emitting light of the first color on the base substrate and an orthographic projection of an electrically connected first pixel circuit on the base substrate may be overlapped. An orthographic projection of a light emitting region of the first light emitting element emitting light of the second color on the base substrate and an orthographic projection of an electrically connected first pixel circuit on the base substrate may be overlapped. An arrangement mode of first pixel circuits and first light emitting elements of the present example may increase a wiring freedom of the first signal trace and the second signal trace, and increase line widths of the first signal trace and the second signal trace, thereby alleviating poor display caused by excessive resistance of the first signal trace and the second signal trace. Furthermore, a display effect of the display substrate may be ensured by compensating a data signal received by a first pixel circuit with which a first light emitting element emitting light of the third color is electrically connected.

In some exemplary implementation modes, an orthographic projection of a first light emitting element emitting light of the third color on the base substrate and an orthographic projection of the second signal trace on the base substrate may be overlapped.

In some exemplary implementation modes, multiple display island regions of the first display region may be arranged in multiple rows and columns, one row of display island regions may include multiple display island regions arranged along the first direction, and one column of display island regions may include multiple display island regions arranged along the second direction. Two adjacent display island regions in at least one column of display island regions may be arranged every other at least one row, and two adjacent display island regions in at least one row of display island regions may be arranged every other at least one column. For example, two adjacent display island regions in a column of display island regions may be arranged every other one row, and two adjacent display island regions in a row of display island regions may be arranged every other one column. In the example, display island regions of adjacent rows may be misplaced in the second direction.

In some exemplary implementation modes, the display island region may include a first first pixel circuit, a second first pixel circuit, a third first pixel circuit, and a fourth first pixel circuit arranged in sequence along the first direction. A third first pixel circuit in a display island region of a k-th row and an m-th column may be electrically connected with a first first pixel circuit of a (k+1)-th row and a (m+1)-th column through a second signal trace, and a fourth first pixel circuit in the display island region of the k-th row and the m-th column may be electrically connected with a second first pixel circuit in the (k+1)-th row and the (m+1)-th column through a second signal trace; wherein k and m are integers.

In some exemplary implementation modes, the four first pixel circuits of the display island region may include a first first pixel circuit, a second first pixel circuit, a third first pixel circuit, and a fourth first pixel circuit arranged in sequence along the first direction. A second signal trace electrically connected with the first first pixel circuit of the display island region may be at least partially parallel to a second signal trace electrically connected with the second first pixel circuit, and a second signal trace electrically connected with the third first pixel circuit may be at least partially parallel to a second signal trace electrically connected with the fourth first pixel circuit. The second signal trace electrically connected with the first first pixel circuit and the second signal traces electrically connected with the fourth first pixel circuit may be substantially symmetrical about a centerline of the four first pixel circuits in the first direction, and the second signal trace electrically connected with the second first pixel circuit and the second signal trace electrically connected with the third first pixel circuit may be substantially symmetrical about the centerline of the four first pixel circuits in the first direction.

In some exemplary implementation modes, a first signal trace and a second signal trace may be located on a side of a first pixel circuit away from the base substrate and located on a side of a first light emitting element close to the base substrate. For example, the first signal trace and the second signal trace may be located on a side of a drive circuit layer away from the base substrate and the drive circuit layer may include multiple first pixel circuits.

In some exemplary implementation modes, the first signal trace and the second signal trace may be of a same layer structure. For example, the display substrate may include a transparent conductive layer and the transparent conductive layer may include first signal trace and second signal trace. However, the embodiment is not limited thereto. For example, the display substrate may include multiple transparent conductive layers, and the first signal trace and the second signal trace may be located in different transparent conductive layers.

In some exemplary implementation modes, the first signal trace may be a straight line segment extending along the first direction and the second signal trace may be a polyline segment extending along the second direction. In the example, by using the first signal trace of the straight line segment to connect first pixel circuits in adjacent display island regions in the first direction, and using the second signal trace of the polyline segment to connect first pixel circuits in adjacent display island regions in the second direction, line widths of the first signal trace and the second signal trace may be increased, loads of the first signal trace and the second signal trace may be reduced, and poor display of the display substrate may be improved.

In some exemplary implementation modes, the display substrate may further include: a second display region located on at least one side of the first display region. The second display region may include multiple second pixel circuits and multiple second light emitting elements disposed on the base substrate, at least one of the multiple second pixel circuits is electrically connected with at least one of the multiple second light emitting elements, the at least one second pixel circuit is configured to drive the at least one second light emitting element to emit light.

Solutions of the embodiments will be described below through some examples.

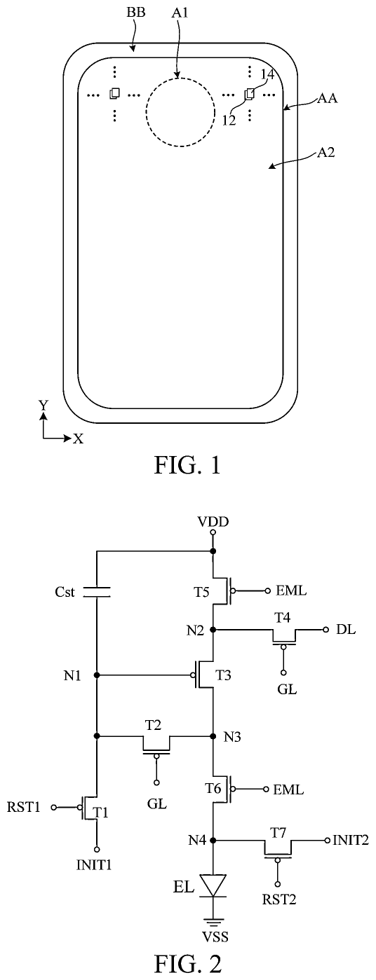

FIG. 1 is a schematic diagram of a display substrate according to at least one embodiment of the present disclosure. In some examples, as shown in FIG. 1, the display substrate may include a display region AA and a peripheral area BB surrounding a periphery of the display region AA. The display region AA of the display substrate may include a first display region A1 and a second display region A2. The second display region A2 may at least partially surround the first display region A1. For Example, the second display region A2 may surround the first display region A1.

In some examples, as shown in FIG. 1, the first display region A1 may be a light-transmitting display region, and may also be referred to as a Full Display with Camera (FDC) region, and the second display region A2 may be a normal display region. For example, an orthographic projection of a photosensitive sensor (such as a camera and other hardware) on the display substrate may be within the first display region A1 of the display substrate. In some examples, as shown in FIG. 1, the first display region A1 may be circular and a size of the orthographic projection of the photosensitive sensor on the display substrate may be less than or equal to a size of the first display region A1. However, the embodiment is not limited thereto. In some other examples, the first display region A1 may be rectangular, and a size of the orthographic projection of the photosensitive sensor on the display substrate may be less than or equal to a size of an inscribed circle of the first display region A1.

In some examples, as shown in FIG. 1, the first display region A1 may be located at a middle position of a top of the display region AA. The second display region A2 may surround a periphery of the first display region A1. However, the embodiment is not limited thereto. For example, the first display region A1 may be located in other positions such as an upper left corner, a lower left corner, a lower right corner, or an upper right corner of the display region AA. For example, the second display region A2 may surround at least a side of the first display region A1.

In some examples, as shown in FIG. 1, the display region AA may be in a shape of a rectangle, e.g., a rounded rectangle. The first display region A1 may be circular or elliptical. However, the embodiment is not limited thereto. For example, the first display region A1 may be rectangular, semicircular, pentagonal, or have another shape.

In some examples, the display region AA may be provided with multiple sub-pixels. At least one sub-pixel may include a pixel circuit and a light emitting element. The pixel circuit is configured to drive a connected light emitting element. For example, the pixel circuit may be configured to provide a drive current to drive the light emitting element to emit light. The pixel circuit may include multiple transistors and at least one capacitor, for example, the pixel circuit may be of a 3T1C (i.e., three transistors and one capacitor) structure, a 7T1C (i.e., seven transistors and one capacitor) structure, a 5T1C (i.e., five transistors and one capacitor) structure, an 8T1C (i.e., eight transistors and one capacitor) structure, or a 8T2C (i.e., eight transistors and two capacitors) structure, or the like.

In some examples, the light emitting element may be any one of a Light Emitting Diode (LED), an Organic Light Emitting Diode (OLED), a Quantum dot Light Emitting Diode (QLED), a Micro LED (including a mini-LED or a micro-LED), and the like. For example, the light emitting element may be an OLED, and the light emitting element may emit red light, green light, blue light, or white light, etc. under drive of a pixel circuit corresponding to the light emitting element. A color of light emitted from the light emitting element may be determined as required. In some examples, the light emitting element may include an anode, a cathode, and an organic emitting layer located between the anode and the cathode. The anode of the light emitting element may be electrically connected with a corresponding pixel circuit. However, the embodiment is not limited thereto.

In some examples, one pixel unit in the display region may include three sub-pixels, which may be a red sub-pixel, a green sub-pixel, and a blue sub-pixel respectively. However, the embodiment is not limited thereto. In some examples, one pixel unit may include four sub-pixels, wherein the four sub-pixels may be a red sub-pixel, a green sub-pixel, a blue sub-pixel, and a white sub-pixel respectively.

In some examples, a shape of the light emitting element may be a rectangle, a rhombus, a pentagon, or a hexagon. When one pixel unit includes three sub-pixels, light emitting elements of the three sub-pixels may be arranged side by side horizontally, side by side vertically, or in a manner like a Chinese character “ [symbol] ”. When one pixel unit includes four sub-pixels, light emitting elements of the four sub-pixels may be arranged side by side horizontally, side by side vertically, or in a manner to form a square. However, the embodiment is not limited thereto.

FIG. 2 is an equivalent circuit diagram of a pixel circuit according to at least one embodiment of the present disclosure. A pixel circuit according to an exemplary embodiment is described by taking a 7T1C structure as an example. However, the embodiment is not limited thereto.

In some exemplary implementation modes, as shown in FIG. 2, the pixel circuit according to the example may include seven transistors (i.e., a first transistor T1 to a seventh transistor T7) and one storage capacitor Cst. A light emitting element EL may include an anode, a cathode, and an organic emitting layer disposed between the anode and the cathode.

In some exemplary implementation modes, the seven transistors of the pixel circuit may be P-type transistors, or may be N-type transistors. Use of a same type of transistors in the pixel circuit may simplify a process flow, reduce a process difficulty of a display substrate, and improve a yield of products. In some possible implementation modes, the seven transistors in the pixel circuit may include a P-type transistor and an N-type transistor.

In some exemplary implementation modes, for the seven transistors in the pixel circuit, a low temperature poly silicon thin film transistor may be adopted, or an oxide thin film transistor may be adopted, or a low temperature poly silicon thin film transistor and an oxide thin film transistor may be adopted. Low Temperature Poly Silicon (LTPS) is adopted for an active layer of a low temperature poly silicon thin film transistor and an oxide semiconductor (Oxide) is adopted for an active layer of an oxide thin film transistor. A low temperature poly silicon thin film transistor has advantages, such as a high mobility and fast charging, while an oxide thin film transistor has advantages, such as a low leakage current. The low temperature poly silicon thin film transistor and the oxide thin film transistor are integrated on one display substrate to form a low temperature polycrystalline oxide (LTPS+Oxide) display substrate, and advantages of both the low temperature poly silicon thin film transistor and the oxide thin film transistor may be utilized, which may achieve low-frequency drive, reduce power consumption, and improve display quality.

In some exemplary implementation modes, as shown in FIG. 2, the display substrate may include a first scan line GL, a data line DL, a first power supply line VDD, a second power supply line VSS, a light emitting control line EML, a first initial signal line INIT1, a second initial signal line INIT2, a second scan line RST1, and a third scan line RST2. In some examples, the first power supply line VDD may be configured to provide a constant first voltage signal to the pixel circuit, and the second power supply line VSS may be configured to provide a constant second voltage signal to the pixel circuit, and the first voltage signal may be greater than the second voltage signal. The first scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the second scan line RST1 may be configured to provide a first reset control signal RESET1 to the pixel circuit, and the third scan line RST2 may be configured to provide a second reset control signal RESET2 to the pixel circuit.

In some examples, a second scan line RST1 electrically connected with a pixel circuit of an n-th row may be electrically connected with a first scan line GL of a pixel circuit of an (n−1)-th row, to be inputted with a scan signal SCAN(n−1), that is, a first reset control signal RESET1(n) is the same as the scan signal SCAN(n−1). A third scan line RST2 of the pixel circuit of the n-th row may be electrically connected with a first scan line GL of the pixel circuit of the n-th row, to be inputted with a scan signal SCAN(n), that is, a second reset control signal RESET2(n) may be the same as the scan signal SCAN(n). Herein, n is an integer greater than 0. Thus, signal lines of the display substrate may be reduced, and a narrow bezel design of the display substrate may be achieved. However, the embodiment is not limited thereto.

In some exemplary implementation modes, the first initial signal line INIT1 may be configured to provide a first initial signal to the pixel circuit, the second initial signal line INIT2 may be configured to provide a second initial signal to the pixel circuit. For example, the first initial signal may be different from the second initial signal. The first initial signal and the second initial signal may be constant voltage signals, and their magnitudes may be between a first voltage signal Vdd and a second voltage signal Vss, but not limited to this. In other examples, the first initial signal and the second initial signal may be the same and only the first initial signal line may be disposed to provide the first initial signal.

In some exemplary implementation modes, as shown in FIG. 2, a gate of the third transistor T3 is electrically connected with a first node N1, a first electrode of the third transistor T3 is electrically connected with a second node N2, and a second electrode of the third transistor T3 is electrically connected with a third node N3. The third transistor T3 may be referred to as a drive transistor. A gate of the fourth transistor T4 is electrically connected with the first scan line GL, a first electrode of the fourth transistor T4 is electrically connected with the data line DL, and a second electrode of the fourth transistor T4 is electrically connected with the first electrode of the third transistor T3. The fourth transistor may be referred to as a data writing transistor. A gate of the second transistor T2 is electrically connected with the first scan line GL, a first electrode of the second transistor T2 is electrically connected with the gate of the third transistor T3, and a second electrode of the second transistor T2 is electrically connected with the second electrode of the third transistor T3. The second transistor may also be referred to as a threshold compensation transistor. A gate of the fifth transistor T5 is electrically connected with the light emitting control line EML, a first electrode of the fifth transistor T5 is electrically connected with the first power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may be referred to as light emitting control transistors. The first transistor T1 is electrically connected with the gate of the third transistor T3 and is configured to reset the gate of the third transistor T3, and the seventh transistor T7 is electrically connected with the anode of the light emitting element EL and is configured to reset the anode of the light emitting element EL. The gate of the first transistor T1 is electrically connected with the second scan line RST1, the first electrode of the first transistor T1 is electrically connected with the first initial signal line INIT1, and the second electrode of the first transistor T1 is electrically connected with the gate of the third transistor T3. A gate of the seventh transistor T7 is connected with the third scan line RST2, a first electrode of the seventh transistor T7 is connected with the second initial signal line INIT2, and a second electrode of the seventh transistor T7 is connected with the anode of the light emitting element EL. The first transistor T1 and the seventh transistor T7 may also be referred to as reset control transistors. A first capacitor electrode plate of the storage capacitor Cst is electrically connected with the gate of the third transistor T3, and a second capacitor electrode plate of the storage capacitor Cst is electrically connected with the first power supply line VDD.

In the example, the first node N1 is a connection point of the storage capacitor Cst, the first transistor T1, the third transistor T3, and the second transistor T2, the second node N2 is a connection point of the fifth transistor T5, the fourth transistor T4, and the third transistor T3, the third node N3 is a connection point of the third transistor T3, the second transistor T2, and the sixth transistor T6, the fourth node N4 is a connection point of the sixth transistor T6, the seventh transistor T7, and the light emitting element EL.

A working process of the pixel circuit will be explained below. Description is given by taking a case in which multiple transistors included in the pixel circuit shown in FIG. 2 are all P-type transistors as an example.

In some exemplary implementation modes, during one-frame display time period, the working process of the pixel circuit may include a first stage, a second stage, and a third stage.

The first stage is referred to as a reset stage. A first reset control signal RESET1 provided by the second scan line RST1 is a low-level signal, so that the first transistor T1 is turned on, and a first initial signal provided by the first initial signal line INIT1 is provided to the first node N1 to initialize the first node N1 and clear an original data voltage in the storage capacitor Cst. A scan signal SCAN provided by the first scan line GL is a high-level signal and a light emitting control signal EM provided by the light emitting control line EML is a high-level signal, so that the fourth transistor T4, the second transistor T2, the fifth transistor T5, the sixth transistor T6, and the seventh transistor T7 are disconnected. In this stage, the light emitting element EL does not emit light.

The second stage is referred to as a data writing stage or a threshold compensation stage. A scan signal SCAN provided by the first scan line GL is a low-level signal, a first reset control signal RESET1 provided by the second scan line RST1 and a light emitting control signal EM provided by the light emitting control line EML are both high-level signals, and the data line DL outputs a data signal DATA. In this stage, the third transistor T3 is turned on since the first capacitor electrode plate of the storage capacitor Cst is at a low-level. The scan signal line SCAN is a low-level signal, so that the second transistor T2, the fourth transistor T4, and the seventh transistor T7 are turned on. The second transistor T2 and the fourth transistor T4 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of the first capacitor electrode plate (i.e., the first node N1) of the storage capacitor Cst is Vdata−|Vth|, wherein Vdata is the data voltage output by the data line DL, and Vth is the threshold voltage of the third transistor T3. The seventh transistor T7 is turned on, so that a second initial signal provided by the second initial signal line INIT2 is provided to the anode of the light emitting element EL to initialize (reset) the anode of the light emitting element EL and clear a pre-stored voltage therein, so as to complete initialization, thereby ensuring that the light emitting element EL does not emit light. The first reset control signal RESET1 provided by the second scan line RST1 is a high-level signal, so that the first transistor T1 is turned off. The light emitting control signal EM provided by the light emitting control signal line EML is a high-level signal, so that the fifth transistor T5 and the sixth transistor T6 are turned off.

The third stage is referred to as a light emitting stage. The light emitting control signal EM provided by the light emitting control line EML is a low-level signal, and the scan signal SCAN provided by the first scan line GL and the first reset control signal RESET1 provided by the second scan line RST1 are high-level signals. The light emitting control signal EM provided by the light emitting control line EML is a low-level signal, so that the fifth transistor T5 and the sixth transistor T6 are turned on, and a first voltage signal output from the first power supply line VDD provides a drive voltage to the anode of the light emitting element EL through the turned-on fifth transistor T5, the third transistor T3, and the sixth transistor T6 to drive the light emitting element EL to emit light.

In a drive process of the pixel circuit, a drive current flowing through the third transistor T3 is determined by a voltage difference between the gate and the first electrode of the third transistor T3. Since the voltage of the first node N1 is Vdata-|Vth|, the drive current of the third transistor T3 is as follows.

I=K×(Vgs−Vth)²=K×[(Vdd−Vdata+|Vth|)−Vth]²=K×[Vdd−Vdata]²

Herein, I is the drive current flowing through the third transistor T3, that is to say, a drive current for driving the light emitting element EL, K is a constant, Vgs is the voltage difference between the gate and the first electrode of the third transistor T3, Vth is the threshold voltage of the third transistor T3, Vdata is the data voltage outputted by the data line DL, and Vdd is the first voltage signal outputted by the first power supply line VDD.

It may be seen from the above formula that a current flowing through the light emitting element EL is independent of the threshold voltage of the third transistor T3. Therefore, the pixel circuit according to the embodiment may better compensate the threshold voltage of the third transistor T3.

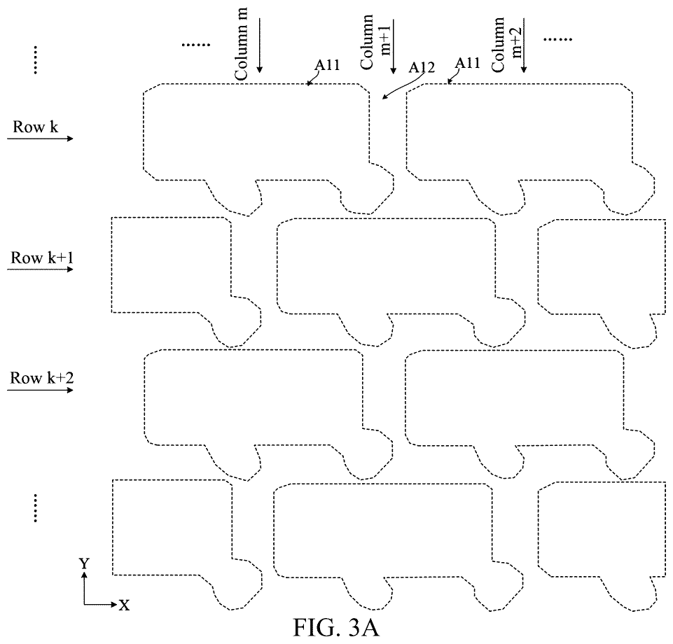

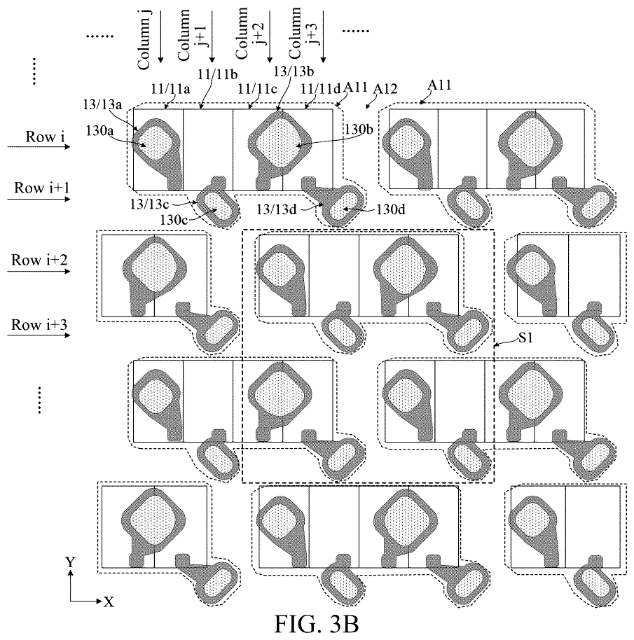

FIG. 3A and FIG. 3B are partial schematic diagrams of a first display region according to at least one embodiment of the present disclosure. In some exemplary implementation modes, as shown in FIGS. 3A and 3B, in a plane parallel to the display substrate, the first display region may include multiple display island regions A11 spaced apart from each other, and a light-transmitting region A12 located between adjacent display island regions A11. Each display island region A11 may be configured to display an image, and each light-transmitting region A12 may be configured to provide a light-transmitting space.

In some examples, as shown in FIG. 3A, shapes of the multiple display island regions A11 may be substantially the same in a plane parallel to the display substrate. A display island region A11 may have a smooth edge, thereby reducing a light diffraction effect and facilitating improvement of a photographing effect. The multiple display island regions A11 in the first display region may be independent of each other, and the light-transmitting regions A12 in the first display region may be communicated. The light-transmitting region A12 may surround the display island region A11.

In some examples, as shown in FIG. 3A, in a plane parallel to the display substrate, multiple display island regions A11 may be arranged in multiple rows and columns. Multiple display island regions A11 arranged along a first direction X may be referred to as a row of display island regions, and multiple display island regions A11 arranged along a second direction Y may be referred to as a column of display island regions. Centerlines of multiple display island regions A11 of a column of display island regions in the first direction X may be substantially aligned. Two adjacent display island regions A11 in a row of display island regions may be arranged every other one column. For example, one of display island regions in a k-th row is located in an m-th column, then a display island region adjacent to the display island region in the k-th row may be located in a (m−2)-th column or in a (m+2)-th column. Two adjacent display island regions A11 in a column of display island regions may be arranged every other one row. For example, one of display island regions in an m-th column is located in a k-th row, then a display island region adjacent to the display island region in the m-th column may be located in a (k−2)-th row or a (k+2)-th row. Herein, both k and m are integers. In the example, display island regions of adjacent rows may be misaligned in the second direction Y, and display island regions of adjacent columns may be misaligned in the first direction X.

In some examples, as shown in FIG. 3B, the first display region may include multiple first pixel circuits 11 and multiple first light emitting elements 13. At least one first pixel circuit 11 and at least one first light emitting element 13 may be electrically connected, and at least one first pixel circuit 11 may be configured to drive the electrically connected at least one first light emitting element 13 to emit light. In the example, the multiple first pixel circuits 11 and the multiple first light emitting elements 13 of the first display region may be electrically connected in one-to-one correspondence.

In some examples, as shown in FIG. 3B, the multiple first light emitting elements 13 of the first display region may include a first light emitting element 13a that emits light of a first color, a first light emitting element 13b that emits light of a second color, and first light emitting elements 13c and 13d that emit light of a third color. The multiple first light emitting elements 11 of the first display region may be arranged according to a Pentile structure. In some examples, first light emitting elements 13a emitting light of the first color and first light emitting elements 13b emitting light of the second color may be alternately arranged in an i-th row, and first light emitting elements 13c and 13d emitting light of the third color may be alternately arranged in an (i+1)-th row at a certain interval. In an (i+2)-th row adjacent to the (i+1)-th row, first light emitting elements 13a emitting light of the first color and first light emitting elements 13b emitting light of the second color may be alternately arranged. First light emitting elements 13c and 13d emitting light of the third color may be alternately arranged at a certain interval in an (i+3)-th row adjacent to the (i+2)-th row. According to the above rule, multiple rows of first light emitting elements 11 may be repeatedly arranged. First light emitting elements 13a which emit light of the first color and first light emitting elements 13b which emit light of the second color arranged in the i-th row, and first light emitting elements 13c and 13d which emit light of the third color arranged in the (i+1)-th row may be arranged alternately. For example, first light emitting elements 13a emitting light of the first color and first light emitting elements 13b emitting light of the second color may be alternately arranged in a j-th column, and first light emitting elements 13c and 13d emitting light of the third color may be arranged at a certain interval in a (j+1)-th column adjacent to the j-th column. First light emitting elements 13a emitting light of the first color and first light emitting elements 13b emitting light of the second color may be alternately arranged in a (j+2)-th column, and first light emitting elements 13c and 13d emitting light of the third color may be arranged at a certain interval in a (j+3)-th column. According to the above rule, multiple columns of first light emitting elements 11 may be repeatedly arranged. Among them, both i and j are integers. In the present disclosure, multiple first light emitting elements arranged along the first direction X may be referred to as a row of first light emitting elements, and multiple first light emitting elements arranged along the second direction Y may be referred to as a column of first light emitting elements.

In some examples, as shown in FIG. 3B, a size of a first light emitting element 13a emitting light of the first color and a size of a first light emitting element 13b emitting light of the second color may be larger than a size of a first light emitting element 13c or 13d emitting light of the third color. For example, the light of the first color may be red light, the light of the second color may be blue light, and the light of the third color may be green light. That is, the first light emitting element emitting light of the first color may be a red light emitting element, the first light emitting element emitting light of the second color may be a blue light emitting element, and the first light emitting element emitting light of the third color may be a green light emitting element. However, the embodiment is not limited thereto.

In some examples, as shown in FIG. 3B, a light emitting region 130a of the first light emitting element 13a emitting light of the first color and a light emitting region 130b of the first light emitting element 13b emitting light of the second color may be substantially rounded rectangular or circular. A light emitting region 130c of the first light emitting element 13c and a light emitting region 130d of the first light emitting element 13d emitting light of the third color may be substantially elliptical. The light emitting region 130a of the first light emitting element 13a emitting light of the first color may be smaller than the light emitting region 130b of the first light emitting element 13b emitting light of the second color. The light emitting region 130b of the first light emitting element 13b emitting light of the second color may be larger than the light emitting region 130c of the first light emitting element 13c emitting light of the third color and the light emitting region 130d of the first light emitting element 13d emitting light of the third color. In the example, a light emitting region of a light emitting element may be a portion where the light emitting element is located at a pixel opening of a pixel definition layer.

In some examples, as shown in FIG. 3B, a single display island region A11 of the first display region may include four first pixel circuits 11 and four first light emitting elements 13. The four first light emitting elements 13 of the display island region A11 may include: a first light emitting element 13a that emits light of a first color, a first light emitting element 13b that emits light of a second color, and two first light emitting elements 13c and 13d that emit light of a third color. Four first pixel circuits 11 of the display island region A11 may be arranged in sequence along the first direction X. The four first pixel circuits 11 of the display island region A11 may include a first pixel circuit 11a electrically connected with a first light emitting element 13a emitting light of a first color, a first pixel circuit 11b electrically connected with a first light emitting element 13c emitting light of a third color, a first pixel circuit 11c electrically connected with a first light emitting element 13b emitting light of a second color, and a first pixel circuit 11d electrically connected with a first light emitting element 13d emitting light of a third color. The first pixel circuits 11a, 11b, 11c, and 11d may be sequentially arranged along the first direction X. In one display island region A11, a first light emitting element 13a emitting light of a first color and a first light emitting element 13b emitting light of a second color may be arranged in a same row, and two first light emitting elements 13c and 13d emitting light of a third color may be arranged in a same row. A first light emitting element 13a emitting light of the first color, one first light emitting element 13c emitting light of the third color, a first light emitting element 13b emitting light of the second color, and the other first light emitting element 13d emitting light of the third color may be arranged in different columns.

In some examples, as shown in FIG. 3B, in the display island region A11, an orthographic projection of the light emitting region 130c of the first light emitting element 13c emitting light of the third color on the base substrate may not be overlapped with an orthographic projection of the electrically connected first pixel circuit 11b on the base substrate. An orthographic projection of the light emitting region 130d of the first light emitting element 13d emitting light of the third color on the base substrate may not be overlapped with an orthographic projection of the electrically connected first pixel circuit 11d on the base substrate. An orthographic projection of the light emitting region 130a of the first light emitting element 13a emitting light of the first color on the base substrate may be overlapped with an orthographic projection of the electrically connected first pixel circuit 11a on the base substrate. For example, an orthographic projection of the light emitting region 130a of the first light emitting element 13a emitting light of the first color on the base substrate may be within a range of an orthographic projection of the first pixel circuit 11a on the base substrate. An orthographic projection of the light emitting region 130b of the first light emitting element 13b emitting light of the second color on the base substrate may be overlapped with an orthographic projection of the electrically connected first pixel circuit 11c on the base substrate. For example, an orthographic projection of the light emitting region 130b of the first light emitting element 13b emitting light of the second color on the base substrate may be partially overlapped with an orthographic projection of the first pixel circuit 11c on the base substrate.

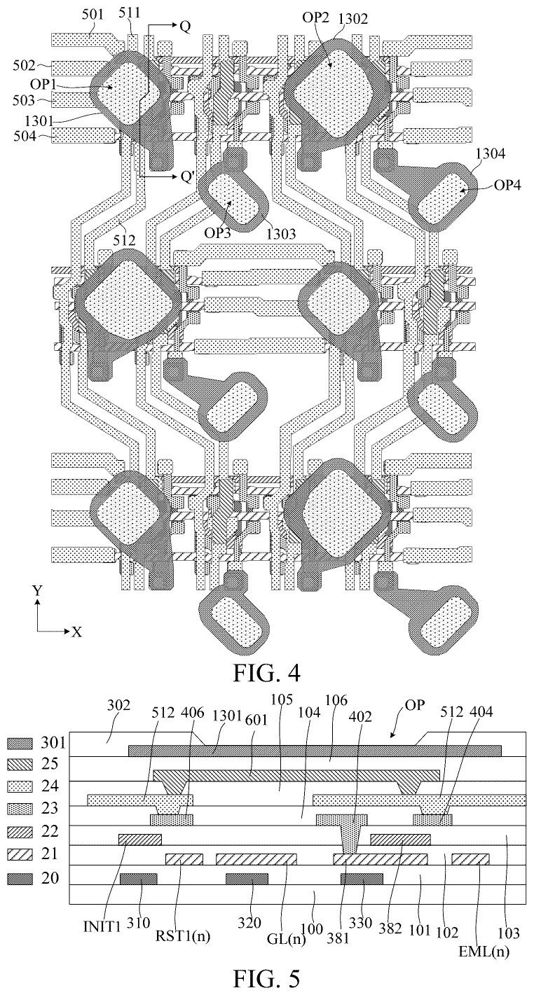

FIG. 4 is a schematic partial top view of a region S1 in FIG. 3B. FIG. 5 is a schematic partial cross-sectional view along a Q-Q′ direction in FIG. 4. Two display island regions adjacent to each other in the second direction Y and parts of the two display island regions adjacent to each other in the first direction X are illustrated in FIG. 4.

In some examples, as shown in FIGS. 4 and 5, in a direction perpendicular to the display substrate, the display substrate may include a base substrate 100, a drive circuit layer, a transparent conductive layer 24, a fourth conductive layer 25, and a light emitting structure layer sequentially disposed on the base substrate. The drive circuit layer may include a semiconductor layer 20, a first conductive layer 21, a second conductive layer 22, and a third conductive layer 23 sequentially disposed on the base substrate 100. A first insulation layer 101 may be disposed between the semiconductor layer 20 and the first conductive layer 21, a second insulation layer 102 may be disposed between the first conductive layer 21 and the second conductive layer 22, and a third insulation layer 103 may be disposed between the second conductive layer 22 and the third conductive layer 23. A fourth insulation layer 104 may be disposed between the third conductive layer 23 and the transparent conductive layer 24. A fifth insulation layer 105 may be disposed between the transparent conductive layer 24 and the fourth conductive layer 25. A sixth insulation layer 106 may be disposed between the fourth conductive layer 25 and an anode layer 301. In some examples, the first insulation layer 101 to the fourth insulation layer 104 may all be inorganic insulation layers, and the fifth insulation layer 105 and the sixth insulation layer 106 may be organic insulation layers. However, the embodiment is not limited thereto.

In some examples, the light emitting structure layer may at least include: the anode layer 301, a pixel definition layer 302, an organic emitting layer, and a cathode layer that are sequentially disposed on the base substrate 100. The anode layer 301 may be electrically connected with a pixel circuit of the drive circuit layer, the organic emitting layer may be connected with the anode layer 301, and the cathode layer may be connected with the organic emitting layer, and the organic emitting layer emits light of a corresponding color under drive of the anode layer 301 and the cathode layer. An encapsulation structure layer may be disposed on a side of the light emitting structure layer away from the base substrate 100. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer may be disposed between the first encapsulation layer and the third encapsulation layer to form a laminated structure of an inorganic material/an organic material/an inorganic material, which may ensure that external water vapor cannot enter the light emitting structure layer. In some possible implementation modes, the display substrate may further include another film layers, such as a touch structure layer and a color filter layer, which is not limited here in the present disclosure.

Exemplary description will be given for a structure and a preparation process of the display substrate below with reference to FIGS. 4 to 16B. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some exemplary implementation modes, a preparation process of a display substrate may include following operations.

(1) A base substrate is provided. In some examples, a base substrate 100 may be a rigid base substrate, or may be a flexible base substrate. For example, the rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In some examples, the flexible base substrate may include a first flexible material layer, a first inorganic material layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNy, y>0) or Silicon Oxide (SiOx, x>0), etc., to improve water-oxygen resistance of the base substrate.

(2) A semiconductor layer is formed. In some examples, a semiconductor thin film is deposited on the base substrate, and the semiconductor thin film is patterned through a patterning process to form a semiconductor layer 20 disposed on the base substrate. In some examples, a material of the semiconductor layer 20 may be amorphous Silicon (a-Si), polycrystalline Silicon (p-Si), hexathiophene, polythiophene, or other materials.

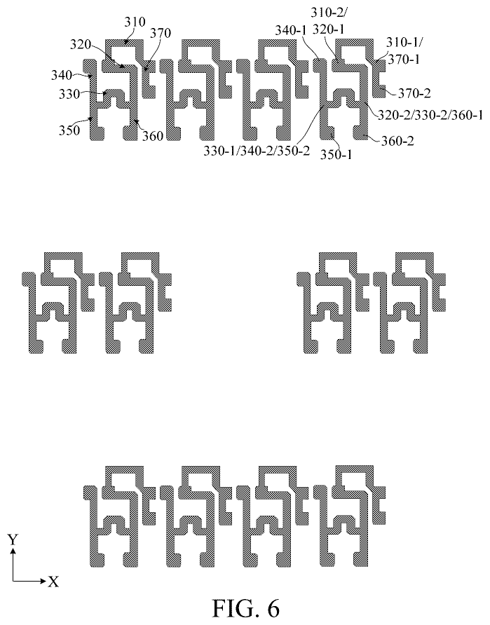

FIG. 6 is a partially enlarged schematic view of the display substrate after a semiconductor layer is formed in FIG. 4. In some examples, as shown in FIG. 6, the semiconductor layer 20 of a single display island A11 of the first display region may at least include: active layers of multiple transistors of four first pixel circuits (e.g., including a first active layer 310 of the first transistor T1, a second active layer 320 of the second transistor T2, a third active layer 330 of the third transistor T3, a fourth active layer 340 of the fourth transistor T4, a fifth active layer 350 of the fifth transistor T5, a sixth active layer 360 of the sixth transistor T6, and a seventh active layer 370 of the seventh transistor T7). The first active layer 310 of the first transistor T1 to the seventh active layer 370 of the seventh transistor T7 of one first pixel circuit may be of an interconnected integral structure.

In some examples, as shown in FIG. 6, the first pixel circuit 11a of the display island region is taken as an example for description. The first active layer 310, the second active layer 320, the fourth active layer 340, and the seventh active layer 370 of the first pixel circuit may be located on a side of the third active layer 330 of the first pixel circuit in the second direction Y. The fifth active layer 350 and the sixth active layer 360 may be located on the other side of the third active layer 330 of the first pixel circuit in the second direction Y.

In some examples, as shown in FIG. 6, a shape of the first active layer 310 of the first pixel circuit may be substantially U-shaped, a shape of the second active layer 320 may be substantially L-shaped, a shape of the third active layer 330 may be substantially n-shaped, and shapes of the fourth active layer 340, the fifth active layer 350, the sixth active layer 360, and the seventh active layer 370 may all be substantially I-shaped. However, the embodiment is not limited thereto.

In some examples, as shown in FIG. 6, the active layer 310 of the first transistor 31 to the active layer 370 of the seventh transistor 37 of the first pixel circuit may each include: a first region, a second region, and a channel region located between the first region and the second region. A first region 340-1 of the fourth active layer 340, a first region 350-1 of the fifth active layer 350, a second region 360-2 of the sixth active layer 360, and a second region 370-2 of the seventh active layer 370 may be individually disposed. A first region 310-1 of the first active layer 310 may also serve as a first region 370-1 of the seventh active layer 370. A second region 310-2 of the first active layer 310 may also serve as a first region 320-1 of the second active layer 320. A second region 320-2 of the second active layer 320 may also serve as a second region 330-2 of the third active layer 330 and a first region 360-1 of the sixth active layer 360. A first region 330-1 of the third active layer 330 may also serve as a second region 340-2 of the fourth active layer 340 and a second region 350-2 of the fifth active layer 350.

(3) A first conductive layer is formed. In some examples, a first insulation thin film and a first conductive thin film are deposited sequentially on the base substrate 100 on which the aforementioned pattern is formed, and the first conductive thin film is patterned through a patterning process to form a first insulation layer and a first conductive layer 21 disposed on the first insulation layer 101. In some examples, the first conductive layer may be referred to as a first gate metal layer.

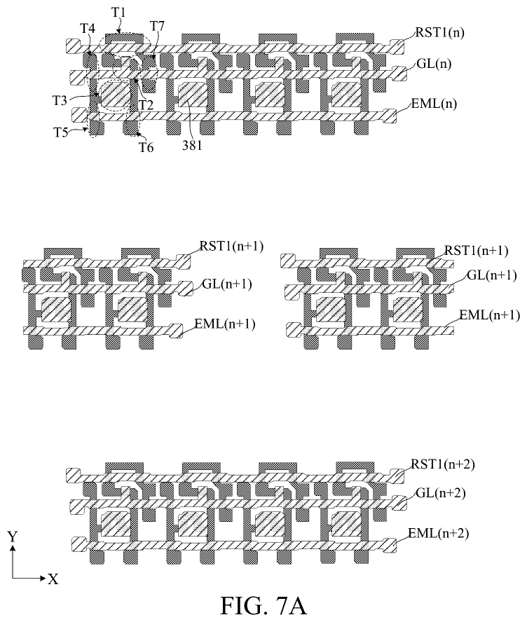

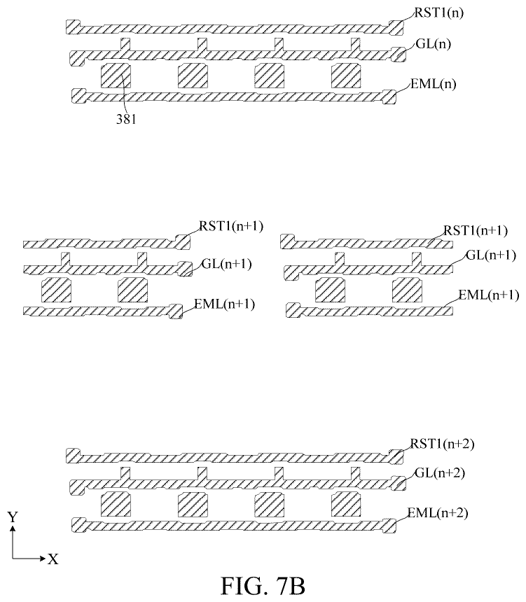

FIG. 7A is a partially enlarged schematic view of the display substrate after a first conductive layer is formed in FIG. 4. FIG. 7B is a schematic diagram of a first conductive layer in FIG. 7A. In some examples, as shown in FIGS. 7A and 7B, the first conductive layer 21 of a single display island region of the first display region may at least include: a first scan line (e.g., a first scan line GL(n), GL(n+1), or GL(n+2)), a second scan line (e.g., a second scan line RST1(n), RST1(n+1), or RST1(n+2)), a light emitting control line (e.g., a light emitting control line EML(n), EML(n+1), or EML(n+2)), and a first capacitor electrode plate 381 of a storage capacitor of the first pixel circuit. The first capacitor electrode plate 381 of the storage capacitor of the first pixel circuit may simultaneously serve as a gate of the third transistor T3. An orthographic projection of the first capacitor electrode plate 381 on the base substrate may be a rectangle, for example, a rounded rectangle. The first scan line, the second scan line, and the light emitting control line may extend along the first direction X in the display island region. In one display island region, the first scan line may be located between the second scan line and the light emitting control line.

In some examples, as shown in FIG. 7A, an overlapping region of the second scan line RST1(n) and the first active layer 310 may serve as a gate of the first transistor T1. An overlapping region of the first scan line GL(n) and the second active layer 320 may serve as a gate of the second transistor T2, an overlapping region of the first scan line GL(n) and the fourth active layer 340 may serve as a gate of the fourth transistor T4, and an overlapping region of the first scan line GL(n) and the seventh active layer 370 may serve as a gate of the seventh transistor T7. An overlapping region of the light emitting control line EML(n) and the fifth active layer 350 may serve as a gate of the fifth transistor T5, and an overlapping region of the light emitting control line EML(n) and the sixth active layer 360 may serve as a gate of the sixth transistor T6. In the example, the first transistor T1 and the second transistor T2 may be double-gate transistors. However, the embodiment is not limited thereto.

In some examples, after the first conductive layer 21 is formed, the light-transmitting region of the first display region may include the base substrate 100 and the first insulation layer 101 disposed on the base substrate 100.

(4) A second conductive layer is formed. In some examples, a second insulation thin film and a second conductive thin film are sequentially deposited on the base substrate 100 on which the aforementioned patterns are formed, and the second conductive thin film is patterned through a patterning process to form a second insulation layer 102 covering the first conductive layer 21 and a second conductive layer 22 disposed on the second insulation layer 102. In some examples, the second conductive layer 22 may also be referred to as a second gate metal layer.

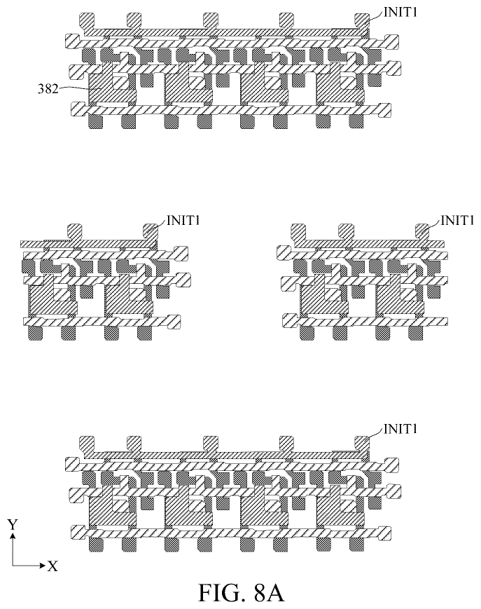

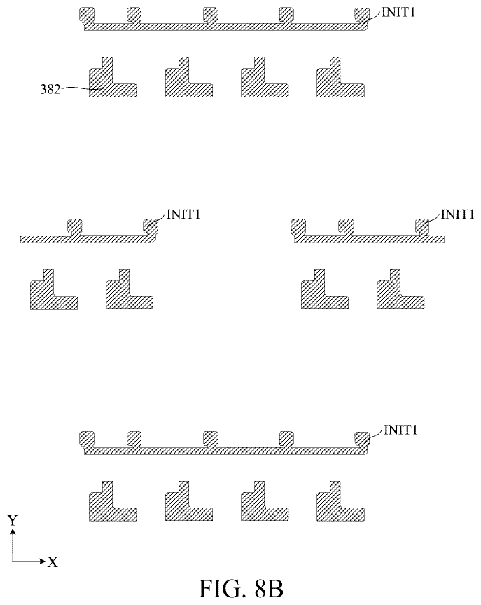

FIG. 8A is a partially enlarged schematic view of the display substrate after a second conductive layer is formed in FIG. 4. FIG. 8B is a schematic diagram of the second conductive layer in FIG. 8. In some examples, as shown in FIGS. 8A and 8B, the second conductive layer 22 of a single display island region of the first display region may at least include a first initial signal line INIT1 and a second capacitor electrode plate 382 of the storage capacitor of the first pixel circuit. An orthographic projection of the second capacitor electrode plate 382 of the storage capacitor of the first pixel circuit on the base substrate may be overlapped with an orthographic projection of the first capacitor electrode plate 381 on the base substrate. For example, an orthographic projection of the second capacitor electrode plate 382 on the base substrate may be substantially L-shaped. The first initial signal line INIT1 may extend along the first direction X in the display island region. In one display island region, an orthographic projection of the first initial signal line INIT1 on the base substrate may be located on a side of the second scan line away from the first scan line.

In some examples, after the second conductive layer 22 is formed, the light-transmitting region of the first display region may include: the base substrate 100, and the first insulation layer 101 and the second insulation layer 102 sequentially disposed on the base substrate 100.

(5) A third insulation layer is formed. In some examples, a third insulation thin film is deposited on the base substrate 100 on which the aforementioned patterns are formed, and the third insulation thin film is patterned through a patterning process to form a third insulation layer 103.

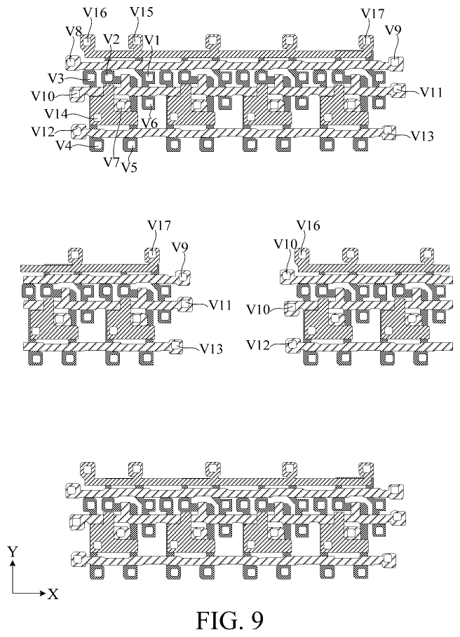

FIG. 9 is a partially enlarged schematic view of the display substrate after a third insulation layer is formed in FIG. 4. In some examples, as shown in FIG. 9, the third insulation layer 103 of a single display island region of the first display region may be provided with multiple vias, which may include, for example: a first via V1 to a seventeenth via V17. Among them, the third insulation layer 103, the second insulation layer 102, and the first insulation layer 101 within the first via V1 to the sixth via V6 may be removed to expose a surface of the semiconductor layer 20. The third insulation layer 103 and the second insulation layer 102 within the seventh via V7 to the thirteenth via V13 may be removed to expose a surface of the first conductive layer 21. The third insulation layer 103 within the fourteenth via V14 to the seventeenth via V17 may be removed to expose a surface of the second conductive layer 22.

(6) A third conductive layer is formed. In some examples, a third conductive thin film is deposited on the base substrate 100 on which the aforementioned patterns are formed, and the third conductive thin film is patterned through a patterning process to form a third conductive layer 23. In some examples, the third conductive layer 23 may also be referred to as a first source-drain metal layer.

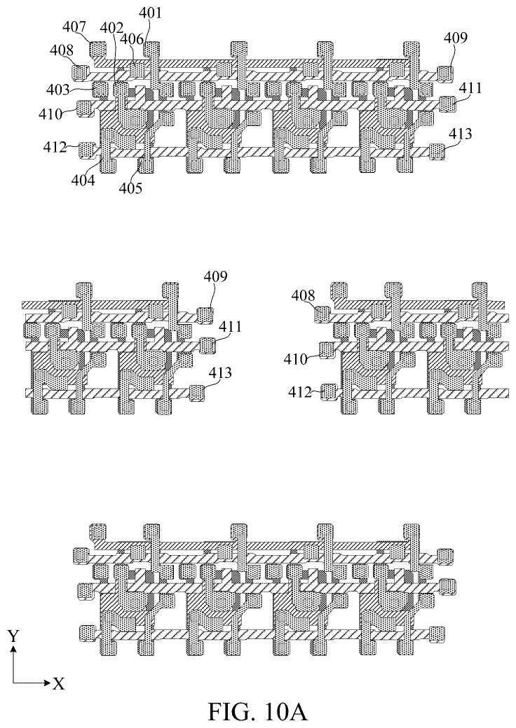

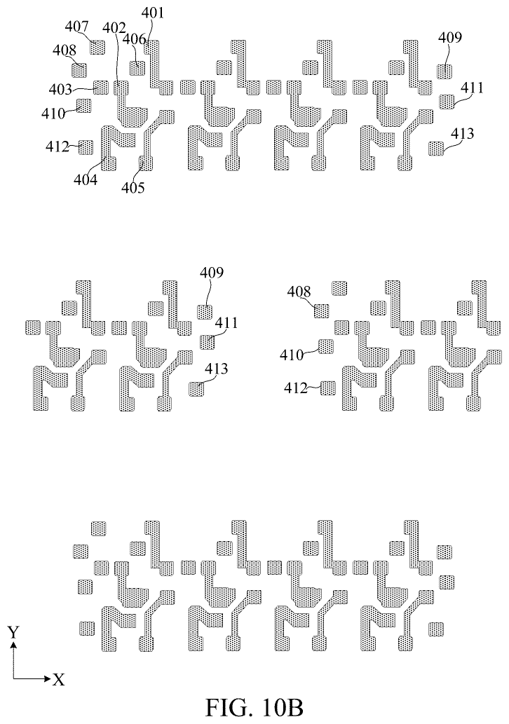

FIG. 10A is a partially enlarged schematic view of the display substrate after a third conductive layer is formed in FIG. 4. FIG. 10B is a schematic diagram of the third conductive layer in FIG. 10A. In some examples, as shown in FIGS. 10A and 10B, the third conductive layer 23 of a single display island region of the first display region may at least include multiple connection electrodes (including, for example, a first connection electrode 401 to a thirteenth connection electrode 413).

In some examples, as shown in FIGS. 9, 10A, and 10B, illustration is made by taking one first pixel circuit of the display island region as an example. The first connection electrode 401 may be electrically connected with the first region 310-1 of the first active layer 310 of the first transistor T1 through the first via V1, and may also be electrically connected with the first initial signal line INIT1 through the fifteenth via V15. The second connection electrode 402 may be electrically connected with the first region 320-1 of the second active layer 320 of the second transistor T2 through the second via V2, and may also be electrically connected with the gate of the third transistor T3 through the seventh via V7. The third connection electrode 403 may be electrically connected with the first region 340-1 of the fourth active layer 340 of the fourth transistor T4 through the third via V3. The fourth connection electrode 404 may be electrically connected with the first region 350-1 of the fifth active layer 350 of the fifth transistor T5 through the fourth via V4, and may also be electrically connected with the second capacitor electrode plate 382 of the storage capacitor through the fourteenth via V14. The fifth connection electrode 405 may be electrically connected with the second region 360-2 of the sixth active layer 360 of the sixth transistor T6 through the fifth via V5, and may also be electrically connected with the second region 370-2 of the seventh active layer 370 of the seventh transistor T7 through the sixth via V6.

In some examples, as shown in FIGS. 9, 10A, and 10B, one display island region is taken as an example for illustration. The sixth connection electrode 406 may be located on a side of the first connection electrode 401 close to the second connection electrode 402 in the first direction X. The seventh connection electrode 407 may be electrically connected with one end of the first initial signal line INIT1 through the sixteenth via V16. The eighth connection electrode 408 may be electrically connected with one end of the second scan line RST1(n) through the eighth via V8. The ninth connection electrode 409 may be electrically connected with the other end of the second scan line RST1(n) through the ninth via V9. The tenth connection electrode 410 may be electrically connected with one end of the first scan line GL(n) through the tenth via V10. The eleventh connection electrode 411 may be electrically connected with the other end of the first scan line GL(n) through the eleventh via V11. The twelfth connection electrode 412 may be electrically connected with one end of the light emitting control line EML(n) through the twelfth via V12. The thirteenth connection electrode 413 may be electrically connected with the other end of the light emitting control line EML(n) through the thirteenth via V13.

In some examples, after the third conductive layer 23 is formed, the light-transmitting region of the first display region may include the base substrate 100, and the first insulation layer 101, the second insulation layer 102, and the third insulation layer 103 disposed on the base substrate 100.

Hereto, preparation of a drive circuit layer is completed. The drive circuit layer of a single display island region of the first display region may include four first pixel circuits arranged in sequence along the first direction X.

(7) A fourth insulation layer is formed. In some examples, a fourth insulation thin film is deposited on the base substrate 100 on which the aforementioned patterns are formed, and the fourth insulation thin film is patterned through a patterning process to form a fourth insulation layer 104.

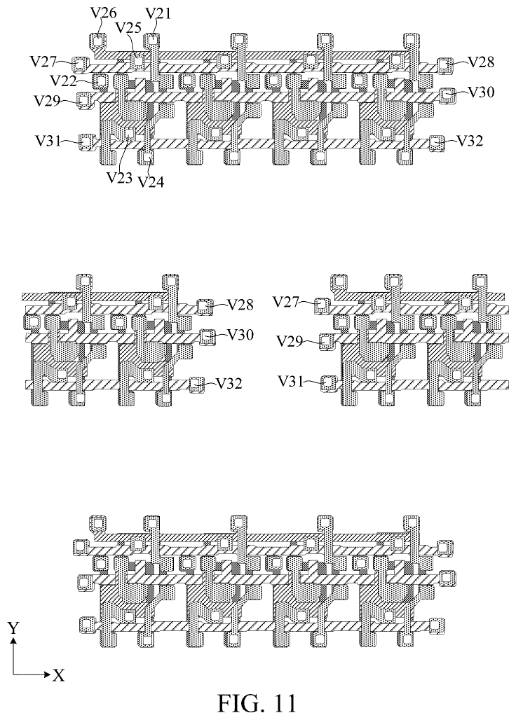

FIG. 11 is a partially enlarged schematic view of the display substrate after a fourth insulation layer is formed in FIG. 4. In some examples, as shown in FIG. 11, the fourth insulation layer 104 of the single display island region of the first display region may be provided with multiple vias, which may include, for example, a twenty-first via V21 to a thirty-second via V32. The fourth insulation layer 104 within the twenty-first via V21 to the thirty-second via V32 may be removed, exposing a surface of the third conductive layer 23.

(8) A transparent conductive layer is formed. In some examples, a transparent conductive thin film is deposited on the base substrate 100 on which the aforementioned patterns are formed, and the transparent conductive thin film is patterned through a patterning process to form a transparent conductive layer 24.

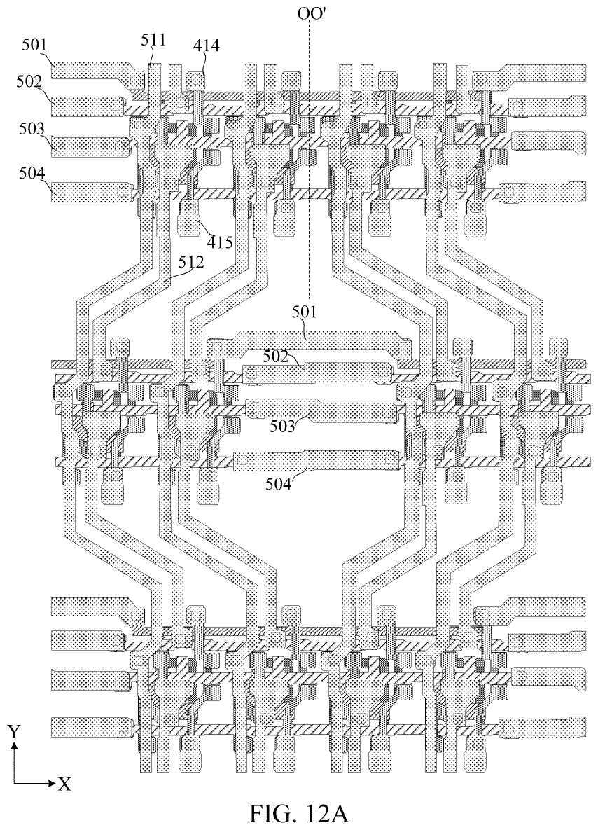

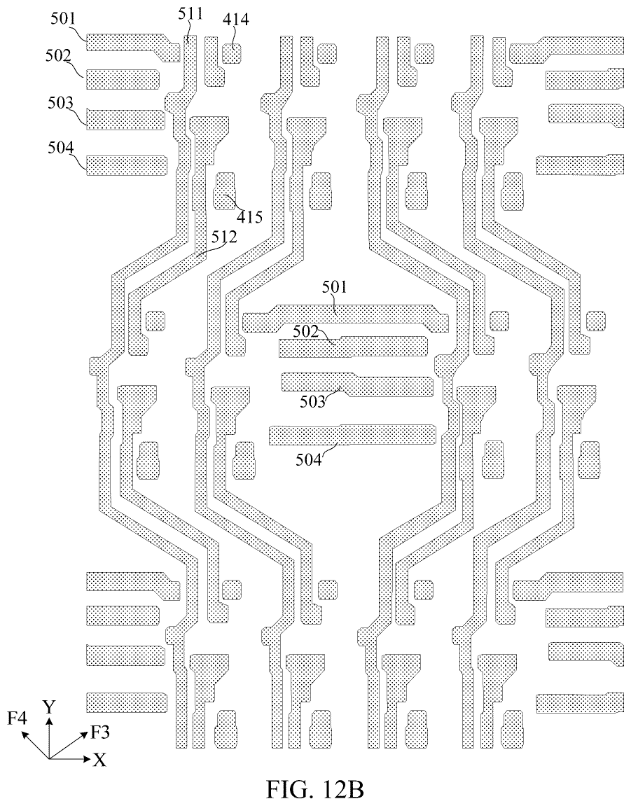

FIG. 12A is a partially enlarged schematic view of the display substrate after a transparent conductive layer is formed in FIG. 4. FIG. 12B is a schematic diagram of the transparent conductive layer in FIG. 12A. In some examples, as shown in FIGS. 12A and 12B, the transparent conductive layer 24 of a single display island region of the first display region may at least include multiple connection electrodes (e.g., including a fourteenth connection electrode 414 and a fifteenth connection electrode 415), multiple connection lines (e.g., including a first connection line 501 to a fourth connection line 504), multiple power supply connection lines 512, and multiple data lines 511.

In some examples, as shown in FIGS. 11, 12A, and 12B, the fourteenth connection electrode 414 may be electrically connected with the first connection electrode 401 through the twenty-first via V21. By providing multiple fourteenth connection electrodes 414 in the display island region, uniformity of a film layer structure may be ensured. The fifteenth connection electrode 415 may be electrically connected with the fifth connection electrode 405 through the twenty-fourth via V24, thereby achieving an electrical connection with the second region 360-2 of the sixth active layer 360 of the sixth transistor T6.

In some examples, as shown in FIGS. 11, 12A, and 12B, one end of the first connection line 501 may be electrically connected with one end of a first initial signal line INIT1 in one display island region through the twenty-sixth via V26; the other end of the first connection line 501 may extend to another display island region through a light-transmitting region, and is electrically connected with one end of a first initial signal line INIT1 in the another display island region through the twenty-first via V21, thereby achieving transmission of a first initial signal between adjacent display island regions in the first direction X.

In some examples, as shown in FIGS. 11, 12A, and 12B, one end of the second connection line 502 may be electrically connected with the eighth connection electrode 408 through the twenty-seventh via V27 to achieve an electrical connection with one end of a second scan line in one display island region; the other end of the second connection line 502 may extend to another display island region through a light-transmitting region, and is electrically connected with the ninth connection electrode 409 through the twenty-eighth via V28 to achieve an electrical connection with one end of a second scan line in the display island region, thereby achieving transmission of a first reset control signal between adjacent display island regions in the first direction X.

In some examples, as shown in FIGS. 11, 12A, and 12B, one end of the third connection line 503 may be electrically connected with the tenth connection electrode 410 through the twenty-ninth via V29 to achieve an electrical connection with one end of a first scan line in one display island region. The other end of the third connection line 503 may extend to another display island region through a light-transmitting region, and is electrically connected with the eleventh connection electrode 411 through the thirtieth via V30 to achieve an electrical connection with one end of a first scan line in the display island region, thereby achieving transmission of a scan signal between adjacent display island regions in the first direction X.

In some examples, as shown in FIGS. 11, 12A, and 12B, one end of the fourth connection line 504 may be electrically connected with the twelfth connection electrode 412 through the thirty-first via V31 to achieve an electrical connection with one end of a light emitting control line in one display island region. The other end of the fourth connection line 504 may extend to another display island region through a light-transmitting region and is electrically connected with the thirteenth connection electrode 413 through the thirty-second via V32 to achieve an electrical connection with one end of a light emitting control line in the display island region, thereby achieving transmission of a light emitting control signal between adjacent display island regions in the first direction X.

In the example, a first signal trace connecting first pixel circuits in adjacent display island regions in the first direction X may include a first connection line 501 to a fourth connection line 504. The first connection line 501 may be a first initial connection line for transmitting a first initial signal. The second connection line 502 may be a second scan connection line for transmitting a first reset control signal. The third connection line 503 may be a first scan connection line for transmitting a scan signal. The fourth connection line 504 may be a light emitting control line for transmitting a light emitting control signal. In some examples, the first connection lines 501 to the fourth connection line 504 may each be a straight line segment extending along the first direction X, i.e., a straight-line trace.

In some examples, as shown in FIGS. 11, 12A, and 12B, a data line 511 may be electrically connected with the third connection electrode 403 through the twenty-second via V22, thereby achieving an electrical connection with the first region 340-1 of the fourth active layer 340 of the fourth transistor T4 of the first pixel circuit. The data line 511 may extend along the second direction Y. In a light-transmitting region between two adjacent display island regions in the second direction Y, the data line 511 may be in a shape of a polyline. A data line electrically connected with a first pixel circuit 11a and a data line electrically connected with a first pixel circuit 11b in one display island region may have a same polyline direction, a data line electrically connected with a first pixel circuit 11c and a data line electrically connected with a first pixel circuit 11d may have a same polyline direction, and a polyline direction of the data line electrically connected with the first pixel circuit 11a may be different from a polyline direction of the data line electrically connected with the first pixel circuit 11c. For example, the data line electrically connected with the first pixel circuit 11a may first extend along the second direction Y from one display island region to the light-transmitting region, then extend along a third direction F3 intersecting with the second direction Y, and finally extend along the second direction Y to the other display island region. Herein, a clockwise included angle from the second direction Y to the third direction F3 may be greater than 0 degree and less than 90 degrees, for example, it may be about 30 degrees, 45 degrees, or 60 degrees, etc. The data line electrically connected with the first pixel circuit 11c may first extend from one display island region to the light-transmitting region along the second direction Y, then extend along a fourth direction F4 intersecting with the second direction Y, and finally extend along the second direction Y to the other display island region. Herein, a clockwise included angle from the second direction Y to the fourth direction F4 may be greater than 90 degrees and less than 180 degrees, for example, it may be about 100 degrees, 120 degrees, or 145 degrees, etc.

In some examples, as shown in FIGS. 11, 12A, and 12B, one end of the power supply connection line 512 may be electrically connected with the fourth connection electrode 404 in one display island region through the twenty-third via V23, and the other end of the power supply connection line 512 may extend to the other display island region through the light-transmitting region and is electrically connected with the sixth connection electrode 406 through the twenty-fifth via V25, thereby achieving transmission of a first voltage signal between adjacent display island regions in the second direction Y. The power supply connection line 512 may be in a shape of a polyline extending along the second direction Y.

In the example, a second signal trace connecting first pixel circuits in adjacent display island regions in the second direction Y may include a data line 511 and a power supply connection line 512. The power supply connection line 512 may be located between adjacent data lines 511 in the first direction X. Polyline directions of a data line 511 and a power supply connection line 512 electrically connected with a same first pixel circuit may be substantially the same. In the example, a first signal trace may be bypassed by setting the second signal trace in a polyline shape, so as to achieve an electrical connection between first pixel circuits in adjacent display island regions.

In some examples, as shown in FIG. 12A, in one display island region, first pixel circuits 11a, 11b, 11c, and 11d from left to right in the first direction X are a first first pixel circuit, a second first pixel circuit, a third first pixel circuit, and a fourth first pixel circuit, respectively. A third first pixel circuit in one display island of a row of display island regions may be electrically connected with a first first pixel circuit in a display island of an adjacent column on a right side of a next row through a second signal trace, and a fourth first pixel circuit in the display island may be electrically connected with a second first pixel circuit in the display island of the adjacent column on the right side of the next row through a second signal trace. A first first pixel circuit in a display island region of a row of display island regions may be electrically connected with a third first pixel circuit in a display island region of an adjacent column on a left side of a next row through a second signal trace, and a second first pixel circuit in the display island region may be electrically connected with a fourth first pixel circuit in the display island region of the adjacent column on the left side of the next row through a second signal trace.

In some examples, as shown in FIG. 12A, a second signal trace electrically connected with a first first pixel circuit in one display island region may be at least partially parallel to a second signal trace electrically connected with a second first pixel circuit, and a second signal trace electrically connected with a third first pixel circuit may be at least partially parallel to a second signal trace electrically connected with a fourth first pixel circuit. The second signal trace electrically connected with the first first pixel circuit and the second signal traces electrically connected with the fourth first pixel circuit may be substantially symmetrical about a centerline OO′ of the four first pixel circuits in the first direction X, and the second signal trace electrically connected with the second first pixel circuit and the second signal trace electrically connected with the third first pixel circuit may be substantially symmetrical about the centerline OO′ of the four first pixel circuits in the first direction X. For example, a data line and a power supply connection line electrically connected with a first first pixel circuit, and a data line and a power supply connection line electrically connected with a second first pixel circuit in the display island region may be at least partially parallel, and a data line and a power supply connection line electrically connected with a third first pixel circuit and a data line and a power supply connection line electrically connected with a fourth first pixel circuit may be at least partially parallel. The data line and the power supply connection line electrically connected with the first first pixel circuit and the data line and the power supply connection line electrically connected with the fourth first pixel circuit may be symmetrically designed, and the data line and the power supply connection line electrically connected with the second first pixel circuit and the data line and the power supply connection line electrically connected with the third first pixel circuit may be symmetrically designed. Therefore, arrangement of first signal traces and second signal traces in a light-transmitting region may be facilitated, and mutual interference may be avoided.

In some examples, after the transparent conductive layer 24 is formed, the light-transmitting region of the first display region may include the base substrate 100, and the first insulation layer 101, the second insulation layer 102, the third insulation layer 103, the fourth insulation layer 104, and the transparent conductive layer disposed on the base substrate 100. The transparent conductive layer 24 of the light-transmitting region may include the first connection line 501 to the fourth connection line 504, the data line 511, and the power supply connection line 512.

(9) A fifth insulation layer is formed. In some examples, a fifth insulation thin film is coated on the base substrate 100 on which the aforementioned patterns are formed, and the fifth insulation thin film is patterned through a patterning process to form a fifth insulation layer 105.

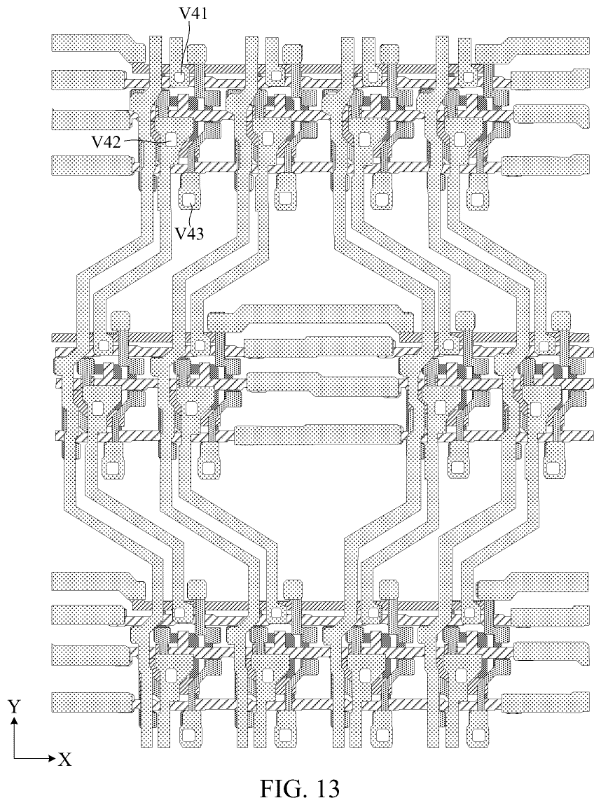

FIG. 13 is a partially enlarged schematic view of the display substrate after a fifth insulation layer is formed in FIG. 4. In some examples, as shown in FIG. 13, the fifth insulation layer 105 of a single display island region of the first display region may be provided with multiple vias, which may include, for example: a forty-first via V41 to a forty-third via V43. The fifth insulation layer 105 within the forty-first via V41 to the forty-third via V43 may be removed to expose a surface of the transparent conductive layer 24.

(10) A fourth conductive layer is formed. In some examples, a fourth conductive thin film is deposited on the base substrate 100 on which the aforementioned patterns are formed, and the fourth conductive thin film is patterned through a patterning process to form a fourth conductive layer 25. In some examples, the fourth conductive layer 25 may also be referred to as a second source-drain metal layer.

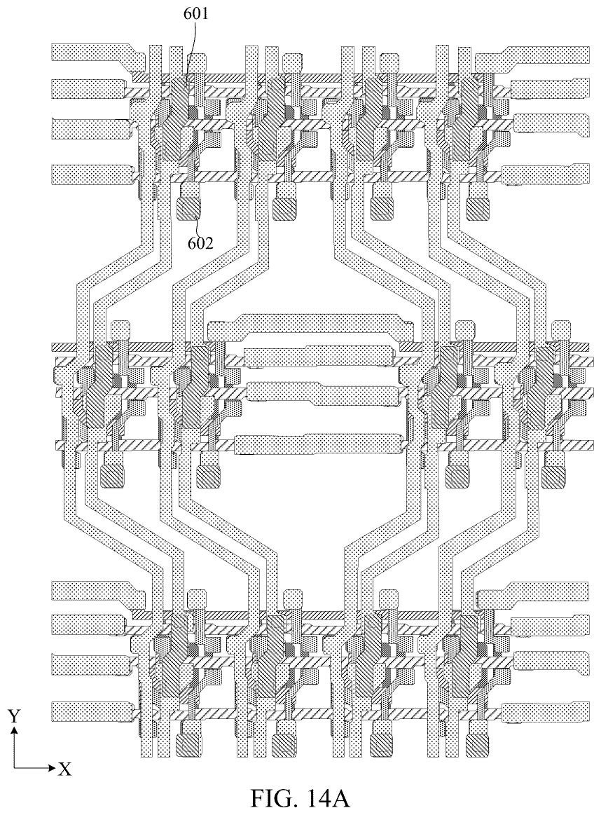

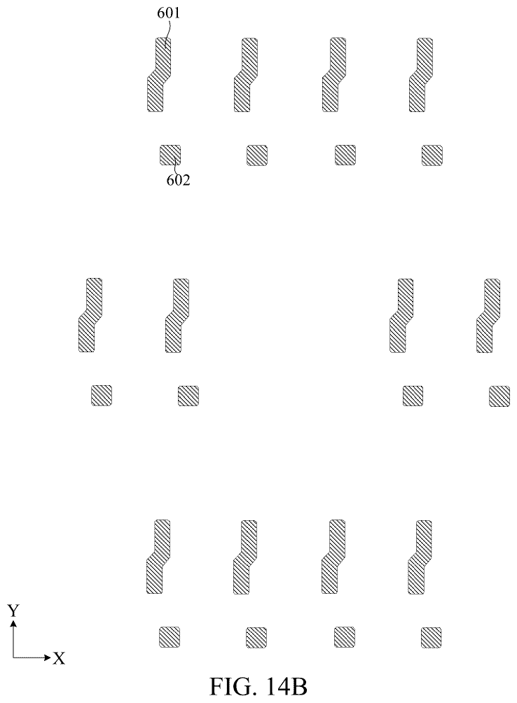

FIG. 14A is a partially enlarged schematic view of the display substrate after a fourth conductive layer is formed in FIG. 4. FIG. 14B is a schematic diagram of the fourth conductive layer in FIG. 14A. In some examples, as shown in FIGS. 14A and 14B, the fourth conductive layer 25 of a single display island region of the first display region may at least include multiple power supply connection electrodes 601 and multiple anode connection electrodes 602.

In some examples, as shown in FIGS. 13, 14A, and 14B, in one display island region, a power supply connection electrode 601 may be electrically connected with one end of one power supply connection line 512 through the forty-first via V41, and may also be electrically connected with one end of another power supply connection line 512 through the forty-second via V42, thereby achieving transmission of a first voltage signal in the display island region. The anode connection electrode 602 may be electrically connected with the fifteenth connection electrode 415 through the forty-third via V43, thereby achieving an electrical connection with a second region 360-2 of a sixth active layer 360 of a sixth transistor T6 of a first pixel circuit.

In some examples, after the fourth conductive layer 25 is formed, the light-transmitting region of the first display region may include the base substrate 100, and the first insulation layer 101, the second insulation layer 102, the third insulation layer 103, the fourth insulation layer 104, the transparent conductive layer 24, and the fifth insulation layer 105 disposed on the base substrate 100.

(11) A sixth insulation layer is formed. In some examples, a sixth insulation thin film is coated on the base substrate 100 on which the aforementioned patterns are formed, and the sixth insulation thin film is patterned through a patterning process to form a sixth insulation layer 106.

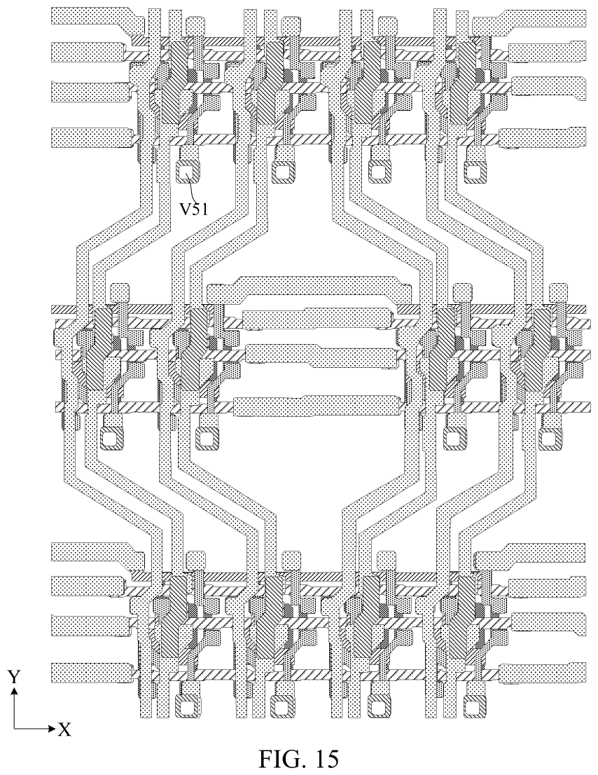

FIG. 15 is a partially enlarged schematic view of the display substrate after a sixth insulation layer is formed in FIG. 4. In some examples, as shown in FIG. 15, the sixth insulation layer 106 of a single display island region of the first display region may be provided with multiple vias, which, for example, may include fifty-first vias V51. The sixth insulation layer 106 within multiple fifty-first vias V51 may be removed to expose a surface of the fourth conductive layer 25.

In some examples, after formation of the sixth insulation layer 106, the light-transmitting region of the first display region may include the base substrate 100, and the first insulation layer 101, the second insulation layer 102, the third insulation layer 103, the fourth insulation layer 104, the transparent conductive layer 24, the fifth insulation layer 105, and the sixth insulation layer 106 that are sequentially disposed on the base substrate 100.

(12) An anode layer is formed. In some examples, an anode thin film is deposited on the base substrate 100 on which the aforementioned patterns are formed, and the anode thin film is patterned through a patterning process to form an anode layer 301.

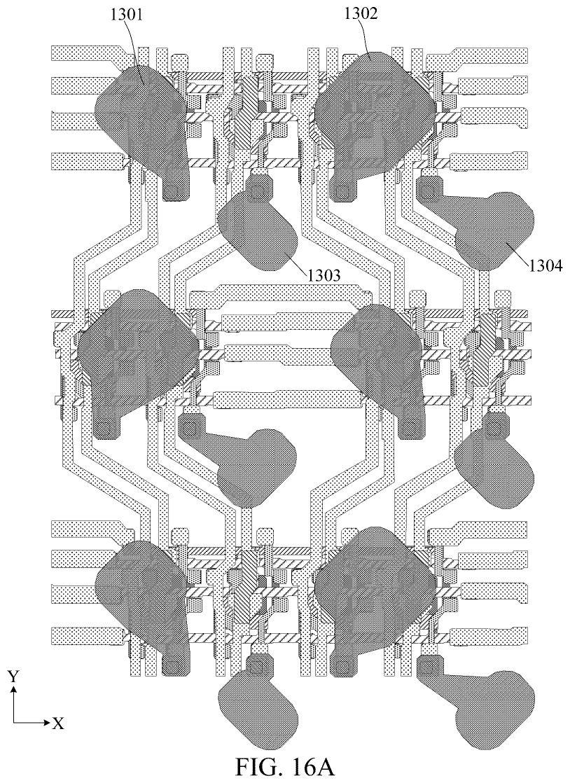

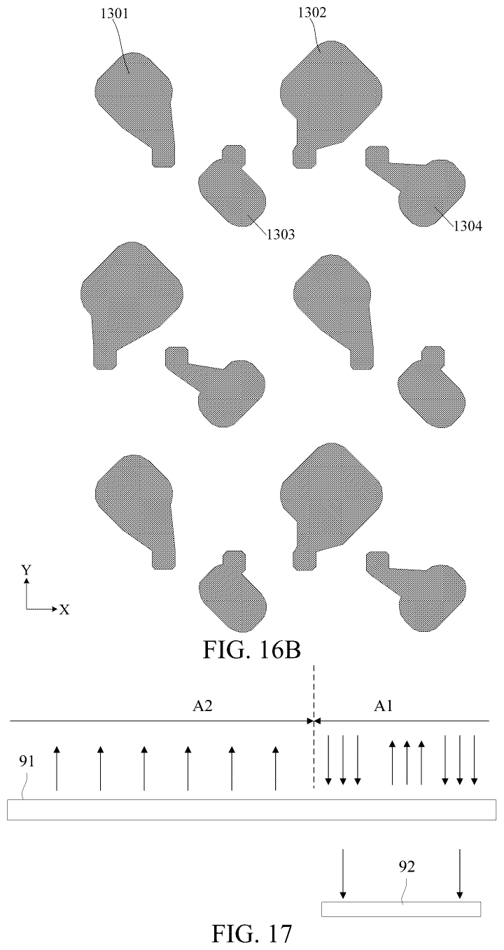

FIG. 16A is a partially enlarged schematic view of the display substrate after an anode layer is formed in FIG. 4. FIG. 16B is a schematic diagram of the anode layer in FIG. 14A. In some examples, as shown in FIGS. 16A and 16B, the anode layer 301 of a single display island region of the first display region may at least include multiple anodes (e.g., including a first anode 1301 of the first light emitting element 13a, a second anode 1303 of the first light emitting element 13b, a third anode 1303 of the first light emitting element 13c, and a fourth anode 1304 of the first light emitting element 13d).

In some examples, as shown in FIGS. 15 and 16A, the first anode 1301 may be electrically connected with an anode connection electrode 602 with which the first pixel circuit 11a is electrically connected through one fifty-first via V51. The second anode 1302 may be electrically connected with an anode connection electrode 602 electrically connected with the first pixel circuit 11c through another fifty-first via V51. The third anode 1303 may be electrically connected with an anode connection electrode 602 electrically connected with the first pixel circuit 11b through another fifty-first via V51. The fourth anode 1304 may be electrically connected with an anode connection electrode 602 electrically connected with the first pixel circuit 11d through another fifty-first via V51.

(13) A pixel definition layer is formed. In some examples, a pixel definition thin film is coated on the base substrate on which the aforementioned patterns are formed, and a Pixel Definition Layer (PDL) is formed through masking, exposure, and development processes.

In some examples, as shown in FIG. 4, a pixel definition layer 302 of a single display island region of the first display region may form a first pixel opening OP1, a second pixel opening OP2, a third pixel opening OP3, and a fourth pixel opening OP4. The first pixel opening OP1 may expose a portion of a surface of the first anode 1301, the second pixel opening OP2 may expose a portion of a surface of the second anode 1302, the third pixel opening OP3 may expose a portion of a surface of the third anode 1303, and the fourth pixel opening OP4 may expose a portion of a surface of the fourth anode 1304.

(14) An organic emitting layer, a cathode layer, and an encapsulation layer are formed. In some examples, organic emitting layers may be respectively formed within the multiple pixel openings formed above, and an organic emitting layer is connected with a corresponding anode. Subsequently, a cathode thin film is deposited, and the cathode thin film is patterned through a patterning process to form a cathode layer, and the cathode layer may be electrically connected with the organic emitting layer and a second power supply line, respectively. Then, an encapsulation layer is formed on the cathode layer. The encapsulation layer may include a stacked structure of an inorganic material/an organic material/an inorganic material.

In some exemplary implementation modes, the first conductive layer 21, the second conductive layer 22, the third conductive layer 23, and the fourth conductive layer 25 may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure, or a multi-layer composite structure, such as Mo/Cu/Mo. The transparent conductive layer 24 may be made of a transparent conductive material, such as Indium Tin Oxide (ITO). The first insulation layer 101 to the fourth insulation layer 104 may be made of any one or more of Silicon Oxide (SiOx, x>0), Silicon Nitride (SiNy, y>0), and Silicon Oxynitride (SiON), and may be a single layer, a multi-layer, or a composite layer. The fifth insulation layer 105 to the sixth insulation layer 106 may be referred to as planarization layers, and may be made of organic materials such as polyimide, acrylic, or polyethylene terephthalate. The pixel definition layer 302 may be made of an organic material, such as polyimide, acrylic, or polyethylene terephthalate. The anode layer may be made of a reflective material such as a metal, and the cathode layer may be made of a transparent conductive material. However, the embodiment is not limited thereto.

In some examples, as shown in FIG. 1, the second display region A2 may include multiple second pixel circuits 12 and multiple second light emitting elements 14. At least one second pixel circuit 12 may be electrically connected with at least one second light emitting element 14, and the at least one second pixel circuit 12 may be configured to drive the electrically connected at least one second light emitting element 14 to emit light. For example, the multiple second pixel circuits 12 and the multiple second light emitting elements 14 may be electrically connected in a one-to-one correspondence. The multiple second light emitting elements 14 of the second display region A2 may include a second light emitting element that emits light of a first color, a second light emitting element that emits light of a second color, and a second light emitting element that emits light of a third color. An arrangement mode of the multiple second light emitting elements may be similar to that of the multiple first light emitting elements, so that details will not be repeated herein. In some examples, an orthographic projection of a light emitting region of a second light emitting element on the base substrate may be overlapped with an orthographic projection of an electrically connected second pixel circuit on the base substrate. In some examples, electrical connections between adjacent second pixel circuits of the second display region does not have to be made through a trace of the transparent conductive layer, and the second display region may not need to be provided with a transparent conductive layer. Rest of a film layer structure of the second display region may be similar to that of the first display region, so details will not be repeated herein.

A structure and a preparation process of the display substrate of the embodiment are merely illustrative. In some exemplary implementation modes, a corresponding structure may be changed and a patterning process may be added or removed according to actual needs. For example, the fourth conductive layer does not have to be provided. For another example, power supply connection lines adjacent to each other along the second direction Y may have an integral structure without being electrically connected through a power supply connection electrode. However, the embodiment is not limited thereto.

The preparation process of the exemplary embodiment may be implemented using an existing mature preparation device, and may be compatible well with an existing preparation process, simple in process implementation, easy to implement, high in a production efficiency, low in a production cost, and high in yield.

In other examples, a display island region may be provided with two first pixel circuits and two first light emitting elements. Multiple display island regions may be arranged in multiple rows and multiple columns, and display island regions in adjacent rows may be aligned in a second direction, and display island regions in adjacent columns may be aligned in a first direction. First pixel circuits of adjacent display island regions in the second direction may be electrically connected through a second signal trace, and the second signal trace may be a straight line segment. First pixel circuits of adjacent display island regions in the first direction may be electrically connected through a first signal trace, and the first signal trace may be a straight line segment. However, the embodiment is not limited thereto.

In some implementation modes, a single display island region of the first display region may be provided with one first light emitting element and one first pixel circuit, and the first pixel circuit may be located below the first light emitting element such that the light-transmitting region is as large as possible. However, when a single first pixel circuit is disposed in the display island region, a spacing between display island regions is relatively small, and winding space of a first signal trace and a second signal trace electrically connecting adjacent first pixel circuits is limited, resulting in the first signal trace and the second signal trace being longer, and line widths and line distances being smaller. Since the first signal trace and the second signal trace are made of a transparent conductive material, taking the transparent conductive material being ITO as an example, a square resistance of ITO is relatively large, and a first pixel circuit is electrically connected with a second pixel circuit of the second display region through the first signal trace and the second signal trace, loads of the first signal trace and the second signal trace which are relatively long will affect display of the second display region adversely and cause poor display. Compared with a solution in which one first light emitting element and one first pixel circuit are disposed in a single display island region and the first pixel circuit is covered by the first light emitting element, in the display substrate provided by the embodiment, multiple first pixel circuits are centrally arranged in a display island region, so that space between display island regions may be increased, an arrangement freedom of the first signal trace and the second signal trace located in the transparent conductive layer may be increased, and wiring space of the first signal trace and the second signal trace may be increased, thereby increasing line widths of the first signal trace and the second signal trace, reducing resistances of the first signal trace and the second signal trace, avoiding poor display of the display substrate caused by loads of the first signal trace and the second signal trace, and supporting a higher refresh rate.

In addition, in the solution in which one first light emitting element and one first pixel circuit are disposed in the single display island region and the first pixel circuit is covered by the first light emitting element, there are many convex display isolated islands and sunken slits, which easily aggravate a light diffraction effect of the first display region and reduces photographing image quality. In the display substrate provided in the embodiment, multiple first pixel circuits are centrally arranged in the display island region, which may reduce a quantity of isolated islands and slits, increase a size of a light-transmitting region between adjacent display island regions, effectively reduce a light diffraction effect, and facilitate smooth processing on an edge of the display island region.

At least one embodiment of the present disclosure also provides a display apparatus, which includes the display substrate as described above.

In some examples, the display apparatus may further include: a sensor located at one side of a non-display surface of the display substrate, and an orthographic projection of the sensor on the display substrate may be overlapped with the first display region of the display substrate.

FIG. 17 is a schematic diagram of a display apparatus according to at least one embodiment of the present disclosure. As shown in FIG. 17, the embodiment provides a display apparatus, which includes a display substrate 91 and a sensor 92 located at a light exit side of a light emitting structure layer away from the display substrate 91. The sensor 92 may be located at a side of a non-display surface of the display substrate 91. An orthographic projection of the sensor 92 on the display substrate 91 may be overlapped with a first display region A1.

In some exemplary implementation modes, the display substrate 91 may be a flexible OLED display substrate, a QLED display substrate, a Micro-LED display substrate, or a Mini-LED display substrate. The display apparatus may be a product having an image (including a still image or a moving image, wherein the moving image may be a video) display function. For example, the display apparatus may be any product of: displays, televisions, billboards, digital photo frames, laser printers with a display function, telephones, mobile phones, picture screens, Personal Digital Assistants (PDA), digital cameras, portable camcorders, viewfinders, navigators, vehicles, large-area walls, information inquiry equipment (such as business inquiry equipment in e-government, banks, hospitals, power departments, and other departments), and monitors, etc. For another example, the display apparatus may be any product of a micro-display, a Virtual Reality (VR) device or an Augmented Reality (AR) device containing a micro-display, etc.

The drawings in the present disclosure only involve structures involved in the present disclosure, and other structures may be referred to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the spirit and scope of the technical solutions of the present disclosure, and shall all fall within the scope of the claims of the present disclosure.

1. A display substrate, comprising: a first display region;
the first display region comprises a plurality of display island regions spaced apart from each other and a light-transmitting region located between adjacent display island regions;
at least one of the display island regions comprises a plurality of first pixel circuits and a plurality of first light emitting elements disposed on a base substrate, at least one first pixel circuit among the plurality of first pixel circuits is electrically connected with at least one first light emitting element among the plurality of first light emitting elements, and the at least one first pixel circuit is configured to drive the at least one first light emitting element to emit light;
first pixel circuits in adjacent display island regions in a first direction are electrically connected through a first signal trace, and first pixel circuits in adjacent display island region in a second direction are electrically connected through a second signal trace; the first direction intersects with the second direction; and materials of the first signal trace and the second signal trace comprise transparent conductive materials.

2. The display substrate according to claim 1, wherein at least portions of the first signal trace and the second signal trace are located in the light-transmitting region.

3. The display substrate according to claim 1, wherein the display island region comprises: four first pixel circuits and four first light emitting elements; the four first pixel circuits are electrically connected with the four first light emitting elements in one-to-one correspondence; and the four first pixel circuits are sequentially arranged along the first direction.

4. The display substrate according to claim 3, wherein the four first light emitting elements comprise: a first light emitting element emitting light of a first color, a first light emitting element emitting light of a second color, and two first light emitting elements emitting light of a third color.

5. The display substrate according to claim 4, wherein the first light emitting element emitting light of the first color and the first light emitting element emitting light of the second color are arranged in a same row, the two first light emitting elements emitting light of the third color are arranged in a same row, and the first light emitting element emitting light of the first color, one first light emitting element emitting light of the third color, the first light emitting element emitting light of the second color, and the other first light emitting element emitting light of the third color are arranged in different columns.

6. The display substrate according to claim 4, wherein orthographic projections of light emitting regions of the two first light emitting elements emitting light of the third color on the base substrate are not overlapped with an orthographic projection of an electrically connected first pixel circuit on the base substrate;
an orthographic projection of a light emitting region of the first light emitting element emitting light of the first color on the base substrate is overlapped with an orthographic projection of an electrically connected first pixel circuit on the base substrate;
an orthographic projection of a light emitting region of the first light emitting element emitting light of the second color on the base substrate is overlapped with an orthographic projection of an electrically connected first pixel circuit on the base substrate.

7. The display substrate according to claim 4, wherein orthographic projections of the first light emitting elements emitting light of the third color on the base substrate are overlapped with an orthographic projection of the second signal trace on the base substrate.

8. The display substrate according to claim 1, wherein the plurality of display island regions are arranged in a plurality of rows and columns, one row of display island regions comprises a plurality of display island regions arranged along the first direction, and one column of display island regions comprises a plurality of display island regions arranged along the second direction; two adjacent display island regions in at least one column of display island regions are arranged every other at least one row, and two adjacent display island regions in at least one row of display island regions are arranged every other at least one column.

9. The display substrate according to claim 8, wherein the display island region comprises: a first first pixel circuit, a second first pixel circuit, a third first pixel circuit, and a fourth first pixel circuit arranged in sequence along the first direction;
a third first pixel circuit in a display island region of a k-th row and an m-th column is electrically connected with a first first pixel circuit of a (k+1)-th row and an (m+1)-th column through the second signal trace, and a fourth first pixel circuit in the display island region of the k-th row and the m-th column is electrically connected with a second first pixel circuit of the (k+1)-th row and the (m+1)-th column through the second signal trace; wherein k and m are integers.

10. The display substrate according to claim 3, wherein the four first pixel circuits comprise a first first pixel circuit, a second first pixel circuit, a third first pixel circuit, and a fourth first pixel circuit arranged in sequence along the first direction;
a second signal trace electrically connected with the first first pixel circuit of the display island region is at least partially parallel to a second signal trace electrically connected with the second first pixel circuit, and a second signal trace electrically connected with the third first pixel circuit is at least partially parallel to a second signal trace electrically connected with the fourth first pixel circuit;
the second signal trace electrically connected with the first first pixel circuit and the second signal trace electrically connected with the fourth first pixel circuit are substantially symmetrical about a centerline of the four first pixel circuits in the first direction, and the second signal trace electrically connected with the second first pixel circuit and the second signal trace electrically connected with the third first pixel circuit are substantially symmetrical about the centerline of the four first pixel circuits in the first direction.

11. The display substrate according to claim 1, wherein the first signal trace and the second signal trace are located on a side of the first pixel circuit away from the base substrate and located on a side of the first light emitting element close to the base substrate.

12. The display substrate according to claim 1, wherein the first signal trace and the second signal trace are of a same layer structure.

13. The display substrate according to claim 1, wherein the first signal trace is a straight line segment extending along the first direction and the second signal trace is a polyline segment extending along the second direction.

14. The display substrate according to claim 1, wherein the first signal trace comprises a first initial connection line for transmitting a first initial signal, a first scan connection line for transmitting a scan signal, a second scan connection line for transmitting a first reset control signal, and a light emitting control line for transmitting a light emitting control signal.

15. The display substrate according to claim 1, wherein the second signal trace comprises: a data line, a power supply connection line for transmitting a first voltage signal.

16. The display substrate according to claim 1, further comprising: a second display region located on at least one side of the first display region; the second display region comprises a plurality of second pixel circuits and a plurality of second light emitting elements disposed on the base substrate, at least one second pixel circuit among the plurality of second pixel circuits is electrically connected with at least one second light emitting element among the plurality of second light emitting elements, and the at least one second pixel circuit is configured to drive the at least one second light emitting element to emit light.

17. A display apparatus, comprising the display substrate according to claim 1.

18. The display apparatus according to claim 17, further comprising a sensor located at one side of a non-display surface of the display substrate, wherein an orthographic projection of the sensor on the display substrate is overlapped with the first display region of the display substrate.

19. The display substrate according to claim 5, wherein orthographic projections of light emitting regions of the two first light emitting elements emitting light of the third color on the base substrate are not overlapped with an orthographic projection of an electrically connected first pixel circuit on the base substrate;
an orthographic projection of a light emitting region of the first light emitting element emitting light of the first color on the base substrate is overlapped with an orthographic projection of an electrically connected first pixel circuit on the base substrate;
an orthographic projection of a light emitting region of the first light emitting element emitting light of the second color on the base substrate is overlapped with an orthographic projection of an electrically connected first pixel circuit on the base substrate.

20. The display substrate according to claim 2, wherein the plurality of display island regions are arranged in a plurality of rows and columns, one row of display island regions comprises a plurality of display island regions arranged along the first direction, and one column of display island regions comprises a plurality of display island regions arranged along the second direction; two adjacent display island regions in at least one column of display island regions are arranged every other at least one row, and two adjacent display island regions in at least one row of display island regions are arranged every other at least one column.
